(19) United States
(12) Patent Application Publication
(10) Pub. No.: US 2026/0282997 A1
(43) Pub. Date: Sep. 17, 2026

(54) SEMICONDUCTOR MODULE AND METHOD FOR MANUFACTURING SEMICONDUCTOR MODULE

(71) Applicant: Nuvoton Technology Corporation Japan, Kyoto (JP)

(72) Inventor: Masahiro HAYASHI, Kyoto (JP)

(21) Appl. No.: 19/669,511

(22) Filed: May 6, 2026

Related U.S. Application Data
(63) Continuation of application No. PCT/JP2024/045712, filed on Dec. 24, 2024.
(60) Provisional application No. 63/614,849, filed on Dec. 26, 2023.

(51) Int. Cl. H10W 72/90; H10D 30/66; H10W 70/65; H10W 72/00; H10W 90/00

(52) U.S. Cl. CPC H10W 72/9445; H10W 70/658; H10W 72/07236; H10W 72/936; H10W 90/724; H10D 30/668

(57) ABSTRACT

A semiconductor module includes: a semiconductor device that includes n pads; and a mounting substrate that includes n lands corresponding one-to-one to the n pads. Each of the n pads is joined by solder bonding material to one of the n lands corresponding to the pad. When among the n pads, Pa denotes an area of a closest pad that is closest to a center of the semiconductor device and Pb denotes an area of a farthest pad that is farthest therefrom, and among the n lands, La denotes an area of a closest land corresponding to the closest pad and Lb denotes an area of a farthest land corresponding to the farthest pad, Pa/La is less than 1 and Pb/Lb is greater than 1, or Pa/La is greater than 1 and Pb/Lb is less than 1.

### CROSS REFERENCE TO RELATED APPLICATIONS

This is a continuation application of PCT International Patent Application No. PCT/JP2024/045712 filed on Dec. 24, 2024, designating the United States of America, which is based on and claims priority of U.S. Provisional Patent Application No. 63/614,849 filed on Dec. 26, 2023. The entire disclosures of the above-identified applications, including the specifications, drawings and claims are incorporated herein by reference in their entirety.

### FIELD

The present disclosure relates to a semiconductor module in which a semiconductor device is mounted above a mounting substrate.

### BACKGROUND

Conventionally, semiconductor modules in which semiconductor devices are mounted above mounting substrates have been known.

### CITATION LIST

### Patent Literature

PTL 1: Japanese Unexamined Patent Application Publication No. 2019-129312
PTL 2: Japanese Unexamined Patent Application Publication No. 2020-038999

### SUMMARY

### Technical Problem

Conventionally, a technique is known for manufacturing a semiconductor module in which a semiconductor device that includes n (n is an integer of 2 or more) pads is reflow-mounted using solder bonding material above a mounting substrate that includes n lands corresponding one-to-one to the n pads.

On the other hand, in semiconductor modules manufactured in this manner, it is important to inhibit the occurrence of defects related to the solder bonding material that joins pads and lands, such as protrusion of the solder bonding material from a pad or a land and insufficiency of the solder bonding material relative to a pad or a land.

In view of this, the present disclosure is to provide, for instance, a semiconductor module that can inhibit the occurrence of defects related to solder bonding material.

### Solution to Problem

A semiconductor module according to an aspect of the present disclosure is a semiconductor module in which a semiconductor device of a chip-size package type including one or more vertical metal oxide semiconductor (MOS) transistors is face-down mounted above a mounting substrate, wherein the semiconductor device includes: a semiconductor layer; a metal layer stacked on the semiconductor layer and in contact with a lower surface of the semiconductor layer, and n (n is an integer of 2 or more) pads disposed in an upper surface of the semiconductor device, the semiconductor device is curved projectingly in a direction in which a center of the semiconductor device in the plan view of the semiconductor device is away from the mounting substrate or projectingly in a direction in which the center thereof is toward the mounting substrate, the mounting substrate includes n lands corresponding one-to-one to the n pads, each of the n pads is joined by solder bonding material to one of the n lands corresponding to the pad, and when the area in the plan view of the semiconductor device of the closest pad that is closest to the center of the semiconductor device in the plan view of the semiconductor device among the n pads is denoted by Pa, the area in the plan view of the semiconductor device of the farthest pad thereamong is denoted by Pb, the area in the plan view of the mounting substrate of the closest land corresponding to the closest pad among the n lands is denoted by La, and the area in the plan view of the mounting substrate of the farthest land corresponding to the farthest pad thereamong is denoted by Lb, Pa/La is less than 1 and Pb/Lb is greater than 1, or Pa/La is greater than 1 and Pb/Lb is less than 1.

A method for manufacturing a semiconductor module according to an aspect of the present disclosure is a method for manufacturing a semiconductor module in which a semiconductor device of a chip-size package type including one or more vertical metal oxide semiconductor (MOS) transistors is face-down mounted above a mounting substrate using a stencil, wherein the semiconductor device includes: a semiconductor layer; a metal layer stacked on the semiconductor layer and in contact with a lower surface of the semiconductor layer; and n (n is an integer of 2 or more) pads disposed in an upper surface of the semiconductor device, the semiconductor device is curved projectingly in a direction in which a center of the semiconductor device in a plan view of the semiconductor device is away from the mounting substrate, the mounting substrate includes n lands corresponding one-to-one to the n pads, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when the area in the plan view of the semiconductor device of the closest pad that is closest to the center of the semiconductor device among the n pads in the plan view of the semiconductor device is denoted by Pa, the area in the plan view of the semiconductor device of the farthest pad thereamong is denoted by Pb, the area in the plan view of the mounting substrate of the closest land corresponding to the closest pad among the n lands is denoted by La, the area in the plan view of the mounting substrate of the farthest land corresponding to the farthest pad thereamong is denoted by Lb, the area in the plan view of the stencil of the closest aperture corresponding to the closest pad among the n apertures is denoted by Sa, and the area in the plan view of the stencil of the farthest aperture corresponding to the farthest pad thereamong is denoted by Sb, Sa is larger than each of Pa and La and/or Sb is smaller than each of Pb and Lb, and the method includes a first process of providing the solder bonding material above each of the n lands by using the stencil, and a second process of joining each of the n pads to one of the n lands corresponding to the pad by performing reflow processing, using the solder bonding material provided above the one of the n lands by performing the first process.

A method for manufacturing a semiconductor module according to an aspect of the present disclosure is a method for manufacturing a semiconductor module in which a semiconductor device of a chip-size package type including one or more vertical metal oxide semiconductor (MOS) transistors is face-down mounted above a mounting substrate using a stencil, wherein the semiconductor device includes: a semiconductor layer; a metal layer stacked on the semiconductor layer and in contact with a lower surface of the semiconductor layer; and n (n is an integer of 2 or more) pads disposed in an upper surface of the semiconductor device, the semiconductor device is curved projectingly in a direction in which a center of the semiconductor device in a plan view of the semiconductor device is toward the mounting substrate, the mounting substrate includes n lands corresponding one-to-one to the n pads, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when Pa denotes the area in the plan view of the semiconductor device of the closest pad that is closest to the center of the semiconductor device among the n pads in the plan view of the semiconductor device, Pb denotes the area in the plan view of the semiconductor device of the farthest pad thereamong, La denotes the area in the plan view of the mounting substrate of the closest land corresponding to the closest pad among the n lands, Lb denotes the area in the plan view of the mounting substrate of the farthest land corresponding to the farthest pad thereamong, Sa denotes the area in the plan view of the stencil of the closest aperture corresponding to the closest pad among the n apertures, and Sb denotes the area in the plan view of the stencil of the farthest aperture corresponding to the farthest pad thereamong, Sa is smaller than each of Pa and La and/or Sb is larger than each of Pb and Lb, and the method includes a first process of providing the solder bonding material above each of the n lands by using the stencil, and a second process of joining each of the n pads to one of the n lands corresponding to the pad by performing reflow processing, using the solder bonding material provided above the one of the n lands by performing the first process.

A method for manufacturing a semiconductor module according to an aspect of the present disclosure is a method for manufacturing the semiconductor module using a stencil, wherein the semiconductor device is projecting in a direction in which a center of the semiconductor device in a plan view of the semiconductor device is away from the mounting substrate, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when Pa denotes an area of a closest pad among the n pads in the plan view of the semiconductor device, La denotes an area of a closest land among the n lands in the plan view of the mounting substrate, and Sa denotes an area of a closest aperture among the n apertures in a plan view of the stencil, the closest pad being closest to the center of the semiconductor device in the plan view of the semiconductor device, the closest land corresponding to the closest pad, the closest aperture corresponding to the closest pad, Sa is larger than each of Pa and La, and the method includes: a first process of providing the solder bonding material above each of the n lands by using the stencil; and a second process of joining each of the n pads to one land corresponding to the pad among the n lands by performing reflow processing, using the solder bonding material provided above the one land by performing the first process.

A method for manufacturing a semiconductor module according to an aspect of the present disclosure is a method for manufacturing the semiconductor module using a stencil, wherein the semiconductor device is projecting in a direction in which a center of the semiconductor device in a plan view of the semiconductor device is away from the mounting substrate, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when Pb denotes an area of a farthest pad among the n pads in the plan view of the semiconductor device, Lb denotes an area of a farthest land among the n lands in the plan view of the mounting substrate, and Sb denotes an area of a farthest aperture among the n apertures in a plan view of the stencil, the farthest pad being farthest from the center of the semiconductor device in the plan view of the semiconductor device, the farthest land corresponding to the farthest pad, the farthest aperture corresponding to the farthest pad, Sb is smaller than each of Pb and Lb, and the method includes: a first process of providing the solder bonding material above each of the n lands by using the stencil; and a second process of joining each of the n pads to one land corresponding to the pad among the n lands by performing reflow processing, using the solder bonding material provided above the one land by performing the first process.

### Advantageous Effects

According to the semiconductor module and the like according to an aspect of the present disclosure, the occurrence of defects related to solder bonding material can be inhibited.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view showing an example of a structure of a semiconductor device according to an embodiment.

FIG. 2 is a cross-sectional view showing an example of the structure of the semiconductor device according to the embodiment.

FIG. 3 is a circuit diagram of the semiconductor device according to the embodiment.

FIG. 4 is a plan view showing an example of a structure of a mounting substrate according to the embodiment.

FIG. 5 is an exploded perspective view showing an example of a structure of a semiconductor module according to the embodiment.

FIG. 6 is a perspective view schematically showing a state in which the semiconductor device according to the embodiment is warping.

FIG. 7 shows an example of a plan view of the semiconductor device according to the embodiment.

FIG. 8 is a schematic cross-sectional view showing how reference radius r is calculated according to the embodiment.

FIG. 9 is a cross-sectional view showing an example of a cross section of the semiconductor module according to the embodiment.

FIG. 10 is a schematic diagram showing examples of the positions and shapes of pads, lands, and solder bonding material in the semiconductor module according to the embodiment.

FIG. 11 is a schematic diagram showing examples of the positions and shapes of pads, lands, and solder bonding material in the semiconductor module according to the embodiment.

FIG. 12 is a plan view of the semiconductor module schematically showing examples of the shapes of pads and lands in the semiconductor module according to Embodiment 1.

FIG. 13 is a plan view of the semiconductor module schematically showing examples of the shapes of pads and lands in the semiconductor module according to Embodiment 1.

FIG. 14 is a cross-sectional view showing an example of a cross section of the semiconductor module according to the embodiment.

FIG. 15 is a schematic diagram showing examples of the positions and shapes of pads, lands, and solder bonding material in the semiconductor module according to the embodiment.

FIG. 16 is a schematic diagram showing examples of the positions and shapes of pads, lands, and solder bonding material in the semiconductor module according to the embodiment.

FIG. 17 is a perspective view showing an example of a structure of a stencil according to the embodiment.

FIG. 18 is a flowchart of semiconductor module manufacturing processing according to the embodiment.

FIG. 19 is a schematic diagram showing the state in which a first process according to the embodiment is being performed.

FIG. 20 is a schematic diagram showing examples of the positions and shapes of pads, lands, and apertures in a method for manufacturing the semiconductor module according to the embodiment.

FIG. 21 is a schematic diagram showing examples of the positions and shapes of pads, lands, and apertures in the method for manufacturing the semiconductor module according to the embodiment.

FIG. 22 is a cross-sectional schematic diagram for explaining an intended relationship between pad shapes and land shapes according to the embodiment.

FIG. 23 is a plan schematic diagram for explaining an intended relationship between pad shapes and land shapes according to the embodiment.

FIG. 24 is a cross-sectional schematic diagram for explaining an intended relationship between pad shapes and land shapes according to the embodiment.

FIG. 25 is a schematic perspective view for explaining an intended relationship between pad shapes and land shapes according to the embodiment.

FIG. 26 is a schematic perspective view for explaining an intended relationship between pad shapes and aperture shapes according to the embodiment.

### DESCRIPTION OF EMBODIMENTS

### Circumstances Leading to Aspects of the Present Disclosure

Conventionally, when a semiconductor device that includes n pads is reflow-mounted using solder bonding material above a mounting substrate that includes n lands corresponding one-to-one to the n pads, a phenomenon is known in which the semiconductor device warps so as to curve projectingly in the direction in which the center of the semiconductor device in the plan view of the semiconductor device is away from the mounting substrate or projectingly in the direction in which the center thereof is toward the mounting substrate.

The warping phenomenon occurs more frequently, for example, when the semiconductor device is configured by stacking a semiconductor layer and a metal layer having a different coefficient of thermal expansion than that of the semiconductor layer.

The inventors diligently conducted experiments and examinations regarding the relationship between the warping phenomenon and the occurrence of defects related to solder bonding material in semiconductor modules.

As a result, the inventors found that when such warping as above occurs in the semiconductor device, the distances between the n pads and the lands corresponding one-to-one to the pads become nonuniform, and consequently, due to this nonuniformity, defects related to solder bonding material that joins the pads and the lands occur more frequently, such as protrusion of the solder bonding material from the pad or land and insufficiency of the solder bonding material relative to the pad or land.

More specifically, the inventors found that (1) when the semiconductor device warps so as to curve projectingly in the direction in which the center of the semiconductor device is away from the mounting substrate, pads that are farther from the center of the semiconductor device have shorter distances to the lands, so the frequency of defects in which the solder bonding material joining the pad and the land protrudes from the pad or the land increases, while pads that are closer to the center of the semiconductor device have longer distances to the lands, so the frequency of defects in which the solder bonding material joining the pad and the land is insufficient relative to the pad or the land increases; and (2) when the semiconductor device warps so as to curve projectingly in the direction in which the center of the semiconductor device is toward the mounting substrate, pads that are closer to the center of the semiconductor device have shorter distances to the lands, so the frequency of defects in which the solder bonding material joining the pad and the land protrudes from the pad or the land increases, while pads that are farther from the center of the semiconductor device have longer distances to the lands, so the frequency of defects in which the solder bonding material joining the pad and the land is insufficient relative to the pad or the land increases.

Based on this finding, the inventors further conducted experiments and examinations. As a result, the inventors conceived the semiconductor module and the like according to the present disclosure.

A semiconductor module according to an aspect of the present disclosure is a semiconductor module in which a semiconductor device of a chip-size package type including one or more vertical metal oxide semiconductor (MOS) transistors is face-down mounted above a mounting substrate, wherein the semiconductor device includes: a semiconductor layer; a metal layer stacked on the semiconductor layer and in contact with a lower surface of the semiconductor layer, and n (n is an integer of 2 or more) pads disposed in an upper surface of the semiconductor device, the semiconductor device is curved projectingly in a direction in which a center of the semiconductor device in the plan view of the semiconductor device is away from the mounting substrate or projectingly in a direction in which the center thereof is toward the mounting substrate, the mounting substrate includes n lands corresponding one-to-one to the n pads, each of the n pads is joined by solder bonding material to one of the n lands corresponding to the pad, and when Pa denotes the area in the plan view of the semiconductor device of the closest pad that is closest to the center of the semiconductor device in the plan view of the semiconductor device among the n pads, Pb denotes the area in the plan view of the semiconductor device of the farthest pad thereamong, La denotes the area in the plan view of the mounting substrate of the closest land corresponding to the closest pad among the n lands, and Lb denotes the area in the plan view of the mounting substrate of the farthest land corresponding to the farthest pad thereamong, Pa/La is less than 1 and Pb/Lb is greater than 1, or Pa/La is greater than 1 and Pb/Lb is less than 1.

According to the semiconductor module having the above configuration, (1) when the semiconductor device is curved projectingly in the direction in which the center of the semiconductor device is away from the mounting substrate, (1-A) by making area Pa of the closest pad smaller than area La of the closest land and making area Pb of the farthest pad larger than area Lb of the farthest land, the occurrence of a defect in which the solder bonding material is insufficient relative to the closest pad and a defect in which the solder bonding material protrudes from the farthest pad can be inhibited.

Alternatively, (1) when the semiconductor device is curved projectingly in the direction in which the center of the semiconductor device is away from the mounting substrate, (1-B) by making area La of the closest land smaller than area Pa of the closest pad and making area Lb of the farthest land larger than area Pb of the farthest pad, the occurrence of a defect in which the solder bonding material is insufficient relative to the closest land and a defect in which the solder bonding material protrudes from the farthest land can be inhibited.

Alternatively, (2) when the semiconductor device is curved projectingly in the direction in which the center of the semiconductor device is toward the mounting substrate, (2-A) by making area Pa of the closest pad larger than area La of the closest land and making area Pb of the farthest pad smaller than area Lb of the farthest land, the occurrence of a defect in which the solder bonding material protrudes from the closest pad and a defect in which the solder bonding material is insufficient relative to the farthest pad can be inhibited.

Alternatively, (2) when the semiconductor device is curved projectingly in the direction in which the center of the semiconductor device is toward the mounting substrate, (2-B) by making area La of the closest land larger than area Pa of the closest pad and making area Lb of the farthest land smaller than area Pb of the farthest pad, the occurrence of a defect in which the solder bonding material protrudes from the closest land and a defect in which the solder bonding material is insufficient relative to the farthest land can be inhibited.

As described above, the occurrence of defects related to solder bonding material can be inhibited according to the semiconductor module having the above configuration.

Furthermore, when with use of mutually distinct n values of k (k being an integer of one to n), each of the n pads is denoted as a k-th pad, each of the n lands corresponding to the n pads indexed by k is denoted as a k-th land, an area of each of the n pads indexed by k in the plan view of the semiconductor device is denoted by P(k), and an area of each of n lands indexed by k in a plan view of the mounting substrate is denoted by L(k), P(k)/L(k) may monotonically increase or monotonically decrease according to a distance in the plan view of the semiconductor device from the center of the semiconductor device to each of the n pads indexed by k.

When the semiconductor device is rectangular in the plan view of the semiconductor device, and D(k) denotes the distance from the center of the semiconductor device to the center of each of the n pads indexed by k in the plan view of the semiconductor device, for each of one or more inner pads, among the n pads indexed by k, which are located inside the circle centered at the center of the semiconductor device in the plan view of the semiconductor device and having a radius denoted by r determined by

$$r = \frac{{\sum }_{k = 1}^{n} D ( k ) \times P ( k )}{{\sum }_{k = 1}^{n} P ( k )} \qquad [ Math 1 ]$$

or r determined by ¼ of the length of the diagonal of the semiconductor device in the plan view of the semiconductor device, P(k)/L(k) may be less than 1, and for each of one or more outer pads, among the n pads indexed by k, which are located outside the above circle in the plan view of the semiconductor device, P(k)/L(k) may be greater than 1.

When the semiconductor device is rectangular in the plan view of the semiconductor device, and D(k) denotes the distance from the center of the semiconductor device to the center of each of the n pads indexed by k in the plan view of the semiconductor device, for each of one or more inner pads, among the n pads indexed by k, which are located inside the circle centered at the center of the semiconductor device in the plan view of the semiconductor device and having a radius denoted by r determined by

$$r = \frac{{\sum }_{k = 1}^{n} D ( k ) \times P ( k )}{{\sum }_{k = 1}^{n} P ( k )} \qquad [ Math 2 ]$$

or r determined by ¼ of the length of the diagonal of the semiconductor device, P(k)/L(k) may be greater than 1, and for each of one or more outer pads, among the n pads indexed by k, which are located outside the above circle, P(k)/L(k) may be less than 1.

When the semiconductor device is curved projectingly in the direction in which the center of the semiconductor device in the plan view of the semiconductor device is away from the mounting substrate, the semiconductor device is a rectangle having sides extending in a first direction and sides extending in a second direction orthogonal to the first direction in the plan view of the semiconductor device, D(k) denotes the distance from the center of the semiconductor device to the center of each of the n pads indexed by k in the plan view of the semiconductor device, r denotes ¼ of the length of the diagonal of the semiconductor device in the plan view of the semiconductor device, XP(k) denotes the length in the first direction of each of the n pads indexed by k in the plan view of the semiconductor device, YP(k) denotes the length in the second direction of each of the n pads indexed by k in the plan view of the semiconductor device, XL(k) denotes the length in the first direction of each of the n lands indexed by k in the plan view of the mounting substrate, YL(k) denotes the length in the second direction of each of the n lands indexed by k in the plan view of the mounting substrate, t denotes the height of the solder bonding material at the position where the distance from the center of the semiconductor device in the plan view of the semiconductor device is r, and a denotes the curvature magnitude of the semiconductor device, for each of one or more inner pads, among the n pads indexed by k, which are located inside the circle centered at the center of the semiconductor device in the plan view of the semiconductor device, either |XP(k)−XL(k)|×YL(k)/2+XL(k)×|YP(k)−YL(k)|/2−|XP(k)−XL(k)|×|YP(k)−YL(k)|/3=XL(k)×YL(k)/[−t/{(2×D(k)/R−½)×a}+1] or |XP(k)−XL(k)|×YP(k)/2+XP(k)×|YP(k)−YL(k)|/2−|XP(k)−XL(k)|×|YP(k)−YL(k)|/3=XP(k)×YP(k)/[−t/{(2×D(k)/R−½)×a}+1] may be satisfied, and for each of one or more outer pads, among the n pads indexed by k, which are located outside the above circle in the plan view of the semiconductor device, either |XP(k)−XL(k)|×YL(k)/2+XL(k)×|YP(k)−YL(k)|/2+|XP(k)−XL(k)|×|YP(k)−YL(k)|/3=XL(k)×YL(k)/[t/{(2×D(k)/R−½)×a}−1] or |XP(k)−XL(k)|×YP(k)/2+XP(k)×|YP(k)−YL(k)|/2+|XP(k)−XL(k)|×|YP(k)−YL(k)|/3=XP(k)×YP(k)/[t/{(2×D(k)/R−½)×a}−1] may be satisfied.

A method for manufacturing a semiconductor module according to an aspect of the present disclosure is a method for manufacturing a semiconductor module in which a semiconductor device of a chip-size package type including one or more vertical metal oxide semiconductor (MOS) transistors is face-down mounted above a mounting substrate using a stencil, wherein the semiconductor device includes: a semiconductor layer; a metal layer stacked on the semiconductor layer and in contact with a lower surface of the semiconductor layer; and n (n is an integer of 2 or more) pads disposed in an upper surface of the semiconductor device, the semiconductor device is curved projectingly in a direction in which a center of the semiconductor device in a plan view of the semiconductor device is away from the mounting substrate, the mounting substrate includes n lands corresponding one-to-one to the n pads, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when the area in the plan view of the semiconductor device of the closest pad that is closest to the center of the semiconductor device among the n pads in the plan view of the semiconductor device is denoted by Pa, the area in the plan view of the semiconductor device of the farthest pad thereamong is denoted by Pb, the area in the plan view of the mounting substrate of the closest land corresponding to the closest pad among the n lands is denoted by La, the area in the plan view of the mounting substrate of the farthest land corresponding to the farthest pad thereamong is denoted by Lb, the area in the plan view of the stencil of the closest aperture corresponding to the closest pad among the n apertures is denoted by Sa, and the area in the plan view of the stencil of the farthest aperture corresponding to the farthest pad thereamong is denoted by Sb, Sa is larger than each of Pa and La and/or Sb is smaller than each of Pb and Lb, and the method includes a first process of providing the solder bonding material above each of the n lands by using the stencil, and a second process of joining each of the n pads to one of the n lands corresponding to the pad by performing reflow processing, using the solder bonding material provided above the one of the n lands by performing the first process.

According to the semiconductor module manufacturing method, in manufacturing a semiconductor module using a semiconductor device that is curved projectingly in a direction in which the center of the semiconductor device is away from the mounting substrate, (1) by making area Sa of the closest aperture larger than each of area Pa of the closest pad and area La of the closest land, the amount of solder bonding material provided above the closest land relative to area Pa of the closest pad and area La of the closest land can be made relatively large.

Accordingly, it is possible to manufacture a semiconductor module in which the occurrence of a defect in which the solder bonding material is insufficient relative to the closest pad and a defect in which the solder bonding material is insufficient relative to the closest land is inhibited.

Alternatively, (2) by making area Sb of the farthest aperture smaller than each of area Pb of the farthest pad and area Lb of the farthest land, the amount of the solder bonding material provided above the farthest land relative to area Pb of the farthest pad and area Lb of the farthest land can be made relatively small.

Accordingly, it is possible to manufacture a semiconductor module in which the occurrence of a defect in which the solder bonding material protrudes from the farthest pad and a defect in which the solder bonding material protrudes from the farthest land are inhibited.

As described above, according to the above semiconductor module manufacturing method, the occurrence of defects related to solder bonding material can be inhibited.

Moreover, when the semiconductor device is rectangular in the plan view of the semiconductor device, and with use of n mutually distinct values of k (where k is an integer between 1 and n, inclusive), each of the n pads is denoted as a k-th pad, each of the n lands corresponding to the n pads indexed by k is denoted as a k-th land, each of the n apertures corresponding to the n pads indexed by k is denoted as a k-th aperture, the area in the plan view of the semiconductor device of each of the n pads indexed by k is denoted by P(k), the area in the plan view of the mounting substrate of each of the n lands indexed by k is denoted by L(k), the area in the plan view of the stencil of each of the n apertures indexed by k is denoted by S(k), and the distance from the center of the semiconductor device to the center of each of the n pads indexed by k in the plan view of the semiconductor device is denoted by D(k), for each of one or more inner pads, among the n pads indexed by k, which are located inside the circle centered at the center of the semiconductor device in the plan view of the semiconductor device and having a radius denoted by r determined by

$$r = \frac{{\sum }_{k = 1}^{n} D ( k ) \times P ( k )}{{\sum }_{k = 1}^{n} P ( k )} \qquad [ Math 3 ]$$

or r determined by ¼ of the length of the diagonal of the semiconductor device, S(k) may be larger than each of P(k) and L(k), and/or for each of one or more outer pads thereamong located outside the above circle in the plan view of the semiconductor device, S(k) may be smaller than each of P(k) and L(k).

For each of the inner pads, S(k)/P(k) may be greater than 1, and for each of the outer pads, S(k)/P(k) may be less than 1.

For each of the inner pads, S(k)/L(k) may be greater than 1, and for each of the outer pads, S(k)/L(k) may be less than 1.

In the plan view of the semiconductor device, the semiconductor device is a rectangle having sides extending in a first direction and sides extending in a second direction orthogonal to the first direction, the shape of the k-th pad in the plan view of the semiconductor device is the same as the shape of the k-th land in the plan view of the mounting substrate, XP(k) denotes the length in the first direction of each of the n pads indexed by k in the plan view of the semiconductor device, YP(k) denotes the length in the second direction of each of the n pads indexed by k in the plan view of the semiconductor device, XS(k) denotes the length in the first direction of each of the n apertures indexed by k in the plan view of the stencil, YS(k) denotes the length in the second direction of each of the n apertures indexed by k in the plan view of the stencil, t denotes the height of the solder bonding material at the position where the distance from the center of the semiconductor device in the plan view of the semiconductor device is r, and a denotes the curvature magnitude of the semiconductor device, for each of the inner pads, |XP(k)−XS(k)|×YP(k)+XP(k)×|YP(k)−YS(k)|+|XP(k)−XS(k)|×|YP(k)−YS(k)|=−{(2×D(k)/R−½)×a}/t×XP(k)×YP(k) may be satisfied, and for each of the outer pads, |XP(k)−XS(k)|×YP(k)+XP(k)×|YP(k)−YS(k)|−|XP(k)−XS(k)|×|YP(k)−YS(k)|={(2×D(k)/R−½)×a}/t×XP(k)×YP(k) may be satisfied.

A method for manufacturing a semiconductor module according to an aspect of the present disclosure is a method for manufacturing a semiconductor module in which a semiconductor device of a chip-size package type including one or more vertical metal oxide semiconductor (MOS) transistors is face-down mounted above a mounting substrate using a stencil, wherein the semiconductor device includes a semiconductor layer, a metal layer stacked on the semiconductor layer and in contact with the lower surface of the semiconductor layer, and n (n is an integer of 2 or more) pads disposed in the upper surface of the semiconductor device, the semiconductor device is curved projectingly in a direction in which the center of the semiconductor device in the plan view of the semiconductor device is toward the mounting substrate, the mounting substrate includes n lands corresponding one-to-one to the n pads, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when Pa denotes the area in the plan view of the semiconductor device of the closest pad that is closest to the center of the semiconductor device in the plan view of the semiconductor device, Pb denotes the area in the plan view of the semiconductor device of the farthest pad therefrom, La denotes the area in the plan view of the mounting substrate of the closest land corresponding to the closest pad among the n lands, Lb denotes the area in the plan view of the mounting substrate of the farthest land corresponding to the farthest pad thereamong, Sa denotes the area in the plan view of the stencil of the closest aperture corresponding to the closest pad among the n apertures, and Sb denotes the area in the plan view of the stencil of the farthest aperture corresponding to the farthest pad thereamong, Sa is smaller than each of Pa and La, and/or Sb is larger than each of Pb and Lb, and the method includes: a first process of providing the solder bonding material above each of the n lands by using the stencil; and a second process of joining each of the n pads to one of the n lands corresponding to the pad by performing reflow processing, using the solder bonding material provided above the one of the n lands by performing the first process.

According to the semiconductor module manufacturing method, in manufacturing a semiconductor module using a semiconductor device that is curved projectingly in a direction in which the center of the semiconductor device is toward the mounting substrate, (1) by making area Sa of the closest aperture smaller than each of area Pa of the closest pad and area La of the closest land, the amount of solder bonding material provided above the closest land relative to area Pa of the closest pad and area La of the closest land can be made relatively small.

Accordingly, it is possible to manufacture a semiconductor module in which the occurrence of a defect in which the solder bonding material protrudes from the closest pad and a defect in which the solder bonding material protrudes from the closest land are inhibited.

Alternatively, (2) by making area Sb of the farthest aperture larger than each of area Pb of the farthest pad and area Lb of the farthest land, the amount of the solder bonding material provided above the farthest land relative to area Pb of the farthest pad and area Lb of the farthest land can be made relatively large.

Accordingly, it is possible to manufacture a semiconductor module in which the occurrence of a defect in which the solder bonding material is insufficient relative to the farthest pad and a defect in which the solder bonding material is insufficient relative to the farthest land are inhibited.

As described above, according to the semiconductor module manufacturing method, the occurrence of defects related to solder bonding material can be inhibited.

A method for manufacturing a semiconductor module according to an aspect of the present disclosure is a method for manufacturing the semiconductor module using a stencil, wherein the semiconductor device is projecting in a direction in which a center of the semiconductor device in a plan view of the semiconductor device is away from the mounting substrate, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when Pa denotes an area of a closest pad among the n pads in the plan view of the semiconductor device, La denotes an area of a closest land among the n lands in the plan view of the mounting substrate, and Sa denotes an area of a closest aperture among the n apertures in a plan view of the stencil, the closest pad being closest to the center of the semiconductor device in the plan view of the semiconductor device, the closest land corresponding to the closest pad, the closest aperture corresponding to the closest pad, Sa is larger than each of Pa and La, and the method includes: a first process of providing the solder bonding material above each of the n lands by using the stencil; and a second process of joining each of the n pads to one land corresponding to the pad among the n lands by performing reflow processing, using the solder bonding material provided above the one land by performing the first process.

According to the semiconductor module manufacturing method, in manufacturing a semiconductor module using a semiconductor device that is curved projectingly in a direction in which the center of the semiconductor device is away from the mounting substrate, by making area Sa of the closest aperture larger than each of area Pa of the closest pad and area La of the closest land, the amount of solder bonding material provided above the closest land relative to area Pa of the closest pad and area La of the closest land can be made relatively large.

Accordingly, it is possible to manufacture a semiconductor module in which the occurrence of a defect in which the solder bonding material is insufficient relative to the closest pad and a defect in which the solder bonding material is insufficient relative to the closest land are inhibited.

As described above, according to the semiconductor module manufacturing method, the occurrence of defects related to solder bonding material can be inhibited.

A method for manufacturing a semiconductor module according to an aspect of the present disclosure is a method for manufacturing the semiconductor module using a stencil, wherein the semiconductor device is projecting in a direction in which a center of the semiconductor device in a plan view of the semiconductor device is away from the mounting substrate, the stencil includes n apertures corresponding one-to-one to the n pads, each of the n apertures is an aperture for providing, above one of the n lands corresponding to the aperture, solder bonding material for joining one of the n pads corresponding to the aperture and the one of the n lands, when Pb denotes an area of a farthest pad among the n pads in the plan view of the semiconductor device, Lb denotes an area of a farthest land among the n lands in the plan view of the mounting substrate, and Sb denotes an area of a farthest aperture among the n apertures in a plan view of the stencil, the farthest pad being farthest from the center of the semiconductor device in the plan view of the semiconductor device, the farthest land corresponding to the farthest pad, the farthest aperture corresponding to the farthest pad, Sb is smaller than each of Pb and Lb, and the method includes: a first process of providing the solder bonding material above each of the n lands by using the stencil; and a second process of joining each of the n pads to one land corresponding to the pad among the n lands by performing reflow processing, using the solder bonding material provided above the one land by performing the first process.

According to the method for manufacturing the semiconductor module, by making area Sb of the farthest aperture smaller than each of area Pb of the farthest pad and area Lb of the farthest land, the amount of the solder bonding material provided above the farthest land relative to area Pb of the farthest pad and area Lb of the farthest land can be made relatively small.

Accordingly, it is possible to manufacture a semiconductor module in which the occurrence of a defect in which the solder bonding material protrudes from the farthest pad and a defect in which the solder bonding material protrudes from the farthest land are inhibited.

As described above, according to the semiconductor module manufacturing method, the occurrence of defects related to solder bonding material can be inhibited.

Below, specific examples of a semiconductor module according to aspects of the present disclosure will be described with reference to the drawings. The embodiments shown herein each show a specific example of the present disclosure. Therefore, the numerical values, shapes, elements, arrangement and connection of the elements, the steps (processes), and the order of the steps shown in the following embodiments are merely examples and are not intended to limit the present disclosure. Furthermore, the drawings are schematic illustrations and are not necessarily depicted with strict accuracy. The same reference signs are used in the drawings for substantially the same configurations, and redundant descriptions are omitted or simplified.

### Embodiments

Below is a description of a semiconductor module according to an embodiment. This semiconductor module is a semiconductor module in which a chip-size-package-type semiconductor device that includes one or more vertical metal oxide semiconductor (MOS) transistors is face-down mounted above a mounting substrate.

### <Structure of Semiconductor Device>

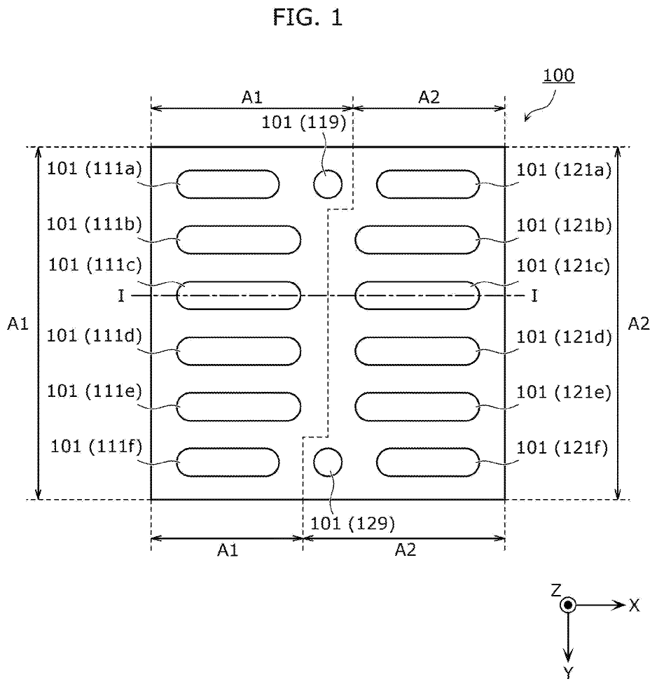

FIG. 1 is a plan view showing an example of the structure of semiconductor device 100 according to the embodiment.

As shown in FIG. 1, semiconductor device 100 is a rectangle having sides extending in a first direction (the X-axis direction in FIG. 1) and sides extending in a second direction (the Y-axis direction in FIG. 1) orthogonal to the first direction, in the plan view of semiconductor device 100.

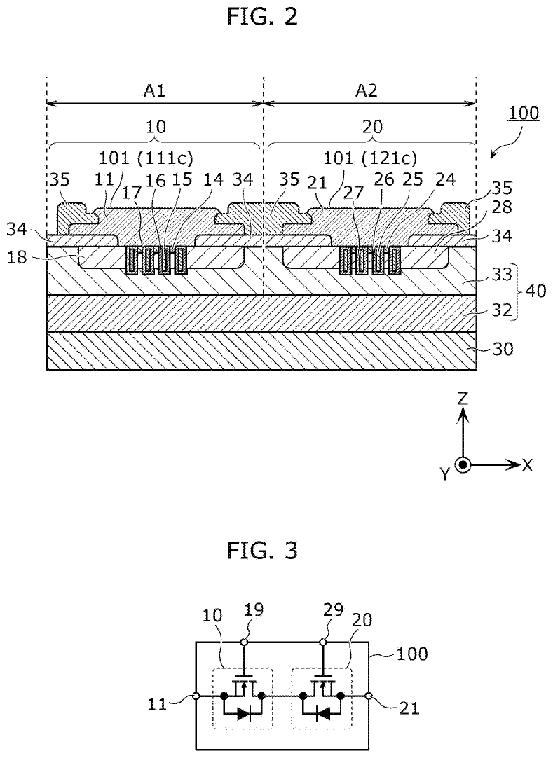

FIG. 2 is a cross-sectional view showing an example of the structure of semiconductor device 100, showing the cross section taken along I-I in FIG. 1.

FIG. 3 is a circuit diagram of semiconductor device 100.

As shown in FIGS. 1 to 3, semiconductor device 100 includes semiconductor layer 40, metal layer 30, oxide film 34, protective film 35, first source electrode 11, second source electrode 21, first gate electrode 19 (not shown in FIGS. 1 and 2, shown only in FIG. 3), and second gate electrode 29 (not shown in FIGS. 1 and 2, shown only in FIG. 3).

Semiconductor device 100 also includes n (n is an integer of 2 or more) pads 101 disposed in the upper surface of semiconductor device 100.

By way of a non-limiting example, n pads 101 included in semiconductor device 100 are described as one or more first source pads 111 (corresponding to first source pads 111a to 111f in FIG. 1; hereafter, when it is unnecessary to distinguish first source pads 111a to 111f from one another explicitly, first source pads 111a to 111f are also referred to simply as “first source pads 111”) and one or more first gate pads 119 (corresponding to first gate pad 119 in FIG. 1), which are disposed in positions included in first region A1 in the plan view of semiconductor device 100; and one or more second source pads 121 (corresponding to second source pads 121a to 121f in FIG. 1; hereafter, when it is unnecessary to distinguish second source pads 121a to 121f from one another explicitly, second source pads 121a to 121f are also referred to simply as “second source pads 121”) and one or more second gate pads 129 (corresponding to second gate pad 129 in FIG. 1), which are disposed in positions included in second region A2 in the plan view of semiconductor device 100.

Stated differently, n pads 101 included in semiconductor device 100 are described herein as a total of fourteen pads, namely, six first source pads 111, one first gate pad 119, six second source pads 121, and one second gate pad 129.

However, n pads 101 included in semiconductor device 100 are not necessarily limited to fourteen pads, as long as there are at least two pads 101.

Semiconductor layer 40 is configured by stacking semiconductor substrate 32 and low-concentration impurity layer 33.

Semiconductor substrate 32 is disposed in the lower portion of semiconductor layer 40 and is made of silicon of a first conductivity type with an impurity at a first concentration.

Low-concentration impurity layer 33 is disposed in the upper portion of semiconductor layer 40, is provided in contact with semiconductor substrate 32, and is made of silicon of the first conductivity type with an impurity at a second concentration lower than the first concentration. Low-concentration impurity layer 33 may be provided above semiconductor substrate 32 by epitaxial growth, for example.

In general, there are two conductivity types for semiconductors, that is, N-type and P-type. The first conductivity type may be N-type or may be P-type. Here, description is given assuming that the first conductivity type is N-type and the second conductivity type described below is P-type. However, the first conductivity type may be P-type, and the second conductivity type may be N-type.

In first region A1 of low-concentration impurity layer 33, first body region 18 with an impurity of the second conductivity type different from the first conductivity type is provided in a portion of semiconductor layer 40 from the upper surface thereof to a first predetermined depth.

In first body region 18, first source regions 14 of the first conductivity type with an impurity are provided in a portion of semiconductor layer 40 ranging from the upper surface thereof to a second predetermined depth and not penetrating through first body region 18.

In first region A1 of low-concentration impurity layer 33, a plurality of first gate trenches 17 extending in the second direction are provided in a portion of semiconductor layer 40 ranging from the upper surface thereof to a third predetermined depth, and penetrating through first source regions 14 and first body region 18 up to a portion of low-concentration impurity layer 33.

First gate conductor 15 extending in the second direction is provided in each of first gate trenches 17, being surrounded by first gate insulating film 16.

First gate conductors 15 are electrically connected to first gate electrode 19.

As a non-limiting example, first gate conductors 15 may be polysilicon with an impurity.

In second region A2 of low-concentration impurity layer 33, second body region 28 with an impurity of the second conductivity type is provided in a portion of semiconductor layer 40 from the upper surface thereof to the first predetermined depth.

In second body region 28, second source regions 24 of the first conductivity type with an impurity are provided in a portion of semiconductor layer 40 ranging from the upper surface thereof to the second predetermined depth and not penetrating through second body region 28.

In second region A2 of low-concentration impurity layer 33, a plurality of second gate trenches 27 extending in the second direction are provided in a portion of semiconductor layer 40 ranging from the upper surface thereof to the third predetermined depth and penetrating through second source regions 24 and second body region 28 up to a portion of low-concentration impurity layer 33.

Second gate conductor 25 extending in the second direction is provided in each of second gate trenches 27, being surrounded by second gate insulating film 26.

Second gate conductors 25 are electrically connected to second gate electrode 29.

As a non-limiting example, second gate conductors 25 may be polysilicon with an impurity.

With the above configuration of semiconductor layer 40, semiconductor device 100 includes first vertical MOS transistor 10 provided in first region A1 of semiconductor layer 40 and second vertical MOS transistor 20 provided in second region A2 of semiconductor layer 40.

With the above configuration of semiconductor layer 40, semiconductor substrate 32 functions as a common drain region in which a first drain region of first vertical MOS transistor 10 and a second drain region of second vertical MOS transistor 20 coexist.

Note that here semiconductor device 100 is described as being configured to include two vertical MOS transistors, namely, first vertical MOS transistor 10 and second vertical MOS transistor 20, but semiconductor device 100 is not necessarily limited to a configuration with two vertical MOS transistors, as long as one or more vertical MOS transistors are included.

Metal layer 30 is provided by being stacked on semiconductor layer 40 and in contact with the lower surface of semiconductor layer 40 and is made of metal. The metal has, for example, a multilayer structure including a layer whose principal component is silver or copper, as a non-limiting example.

Oxide film 34 is disposed above the upper surface of semiconductor layer 40 and is provided in contact with low-concentration impurity layer 33.

Protective film 35 covers the upper surfaces of oxide film 34, first source electrode 11, second source electrode 21, first gate electrode 19, and second gate electrode 29.

Protective film 35 includes an aperture that exposes a portion of the upper surface of first source electrode 11 to the outside of protective film 35, an aperture that exposes a portion of the upper surface of second source electrode 21 to the outside of protective film 35, an aperture that exposes a portion of the upper surface of first gate electrode 19 to the outside of protective film 35, and an aperture that exposes a portion of the upper surface of second gate electrode 29 to the outside of protective film 35.

First source electrode 11 is an electrode whose lower surface is in contact with and connected to first source region 14 and first body region 18, is made of metal, and functions as the source electrode of first vertical MOS transistor 10.

A portion of the upper surface of first source electrode 11 is exposed to the upper surface of semiconductor device 100 through the aperture in protective film 35. The portion of the upper surface of first source electrode 11 exposed to the upper surface of semiconductor device 100 through the aperture in protective film 35 serves as first source pad 111.

Stated differently, first source pad 111 is a portion of the upper surface of first source electrode 11 that is exposed to the upper surface of semiconductor device 100 through an aperture in protective film 35.

First gate electrode 19 is an electrode that is electrically connected to first gate conductors 15, is made of metal, and functions as the gate electrode of first vertical MOS transistor 10.

A portion of the upper surface of first gate electrode 19 is exposed to the upper surface of semiconductor device 100 through the aperture in protective film 35. The portion of the upper surface of first gate electrode 19 exposed to the upper surface of semiconductor device 100 through the aperture in protective film 35 serves as first gate pad 119.

Stated differently, first gate pad 119 is a portion of the upper surface of first gate electrode 19 that is exposed to the upper surface of semiconductor device 100 through the aperture in protective film 35.

Second source electrode 21 is an electrode whose lower surface is in contact with and connected to second source region 24 and second body region 28, is made of metal, and functions as the source electrode of second vertical MOS transistor 20.

A portion of the upper surface of second source electrode 21 is exposed to the upper surface of semiconductor device 100 through the aperture in protective film 35. The portion of the upper surface of second source electrode 21 exposed to the upper surface of semiconductor device 100 through the aperture in protective film 35 serves as second source pad 121.

Stated differently, second source pad 121 is a portion of the upper surface of second source electrode 21 that is exposed to the upper surface of semiconductor device 100 through the aperture in protective film 35.

Second gate electrode 29 is an electrode that is electrically connected to second gate conductors 25, is made of metal, and functions as the gate electrode of second vertical MOS transistor 20.

A portion of the upper surface of second gate electrode 29 is exposed to the upper surface of semiconductor device 100 through the aperture in protective film 35. The portion of the upper surface of second gate electrode 29 exposed to the upper surface of semiconductor device 100 through the aperture in protective film 35 serves as second gate pad 129.

Stated differently, second gate pad 129 is a portion of the upper surface of second gate electrode 29 that is exposed to the upper surface of semiconductor device 100 through the aperture in protective film 35.

### <Structure of Mounting Substrate>

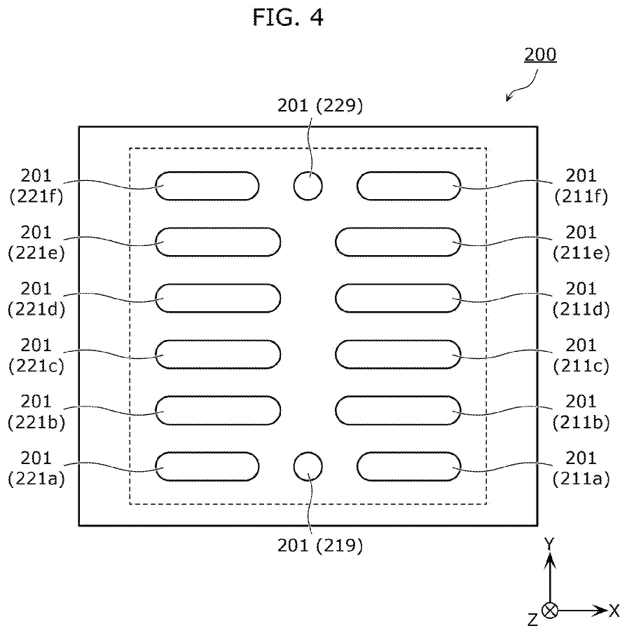

FIG. 4 is a plan view showing an example of the structure of mounting substrate 200 according to the embodiment.

Mounting substrate 200 is a mounting substrate above which semiconductor device 100 is face-down mounted.

The dashed line in FIG. 4 schematically indicates the outline of semiconductor device 100 when semiconductor device 100 is face-down mounted above mounting substrate 200.

Note that in FIG. 4, the ratio between the size defined by the outline of semiconductor device 100 in the plan view of semiconductor device 100 and the size defined by the outline of mounting substrate 200 in the plan view of mounting substrate 200 does not reflect the actual ratio. For example, the actual ratio of the size defined by the outline of mounting substrate 200 in the plan view of mounting substrate 200 to the size defined by the outline of semiconductor device 100 in the plan view of semiconductor device 100 may be higher than the ratio shown by the example in FIG. 4.

As shown in FIG. 4, mounting substrate 200 includes n lands 201 that correspond one-to-one to n pads 101 included in semiconductor device 100.

Thus, when semiconductor device 100 includes first source pads 111a to 111f, second source pads 121a to 121f, first gate pad 119, and second gate pad 129 as shown in FIG. 1, mounting substrate 200 includes, as shown in FIG. 4, first source land 211a corresponding to first source pad 111a, first source land 211b corresponding to first source pad 111b, first source land 211c corresponding to first source pad 111c, first source land 211d corresponding to first source pad 111d, first source land 211e corresponding to first source pad 111e, first source land 211f corresponding to first source pad 111f, second source land 221a corresponding to second source pad 121a, second source land 221b corresponding to second source pad 121b, second source land 221c corresponding to second source pad 121c, second source land 221d corresponding to second source pad 121d, second source land 221e corresponding to second source pad 121e, second source land 221f corresponding to second source pad 121f, first gate land 219 corresponding to first gate pad 119, and second gate land 229 corresponding to second gate pad 129.

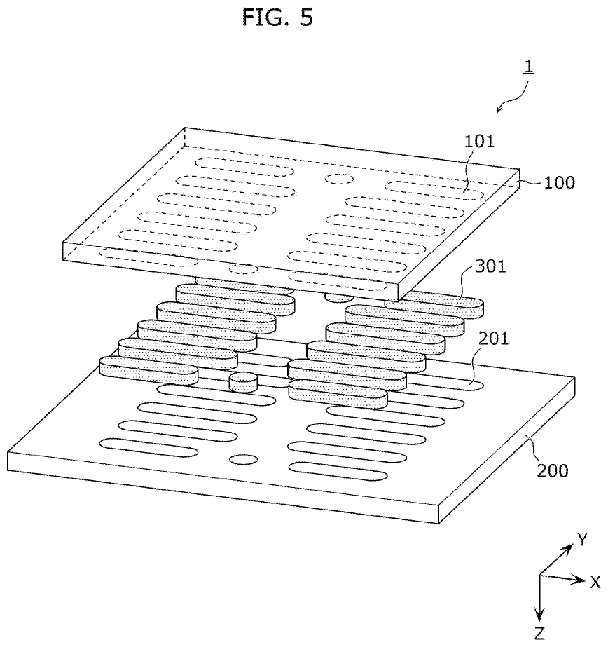

Each of n lands 201 is joined by solder bonding material 301 (see FIG. 5 described below) to, among n pads 101 included in semiconductor device 100, one pad 101 corresponding to that land 201 in a state in which semiconductor device 100 is face-down mounted above mounting substrate 200.

Stated differently, each of n pads 101 is joined by solder bonding material 301 to, among n lands 201 included in mounting substrate 200, one land 201 corresponding to that pad 101 when semiconductor device 100 is face-down mounted above mounting substrate 200.

Each of n lands 201 overlaps, in the plan view of mounting substrate 200, at least a portion of, among n pads 101 included in semiconductor device 100, one pad 101 corresponding to that land 201 in a state in which semiconductor device 100 is face-down mounted above mounting substrate 200.

### <Structure of Semiconductor Module>

FIG. 5 is an exploded perspective view showing an example of the structure of semiconductor module 1 according to the embodiment.

In FIG. 5, n pads 101 are illustrated as if they were visible through semiconductor device 100, but in reality, they cannot be directly viewed through semiconductor device 100.

Note that in FIG. 5, the ratio between the size defined by the outline of semiconductor device 100 in the plan view of semiconductor device 100 and the size defined by the outline of mounting substrate 200 in the plan view of mounting substrate 200 does not reflect the actual ratio. For example, the actual ratio of the size defined by the outline of mounting substrate 200 in the plan view of mounting substrate 200 to the size defined by the outline of semiconductor device 100 in the plan view of semiconductor device 100 may be higher than the ratio shown by the example in FIG. 5.

As shown in FIG. 5, semiconductor module 1 includes semiconductor device 100, mounting substrate 200, and n deposits of solder bonding material 301 that correspond one-to-one to n pads 101 included in semiconductor device 100.

Each of n deposits of solder bonding material 301 joins pad 101 corresponding one-to-one to that solder bonding material 301 and land 201 corresponding one-to-one to that solder bonding material 301.

As described below, semiconductor module 1 is manufactured by a process of joining, by performing reflow processing, each of n pads 101 to one of n lands 201 corresponding to that pad 101 using solder bonding material 301 provided above that land 201.

Accordingly, semiconductor device 100 is face-down mounted above mounting substrate 200 in a state of being heated during the reflow processing in the process of manufacturing semiconductor module 1.

On the other hand, as described above, semiconductor device 100 is configured by stacking semiconductor layer 40 and metal layer 30. In general, semiconductor layer 40 made of silicon and metal layer 30 made of metal have different coefficients of thermal expansion.

Accordingly, when semiconductor device 100 is heated during the reflow processing in the process of manufacturing semiconductor module 1, semiconductor device 100 warps so as to curve projectingly in the direction in which the center of semiconductor device 100 in the plan view of semiconductor device 100 is away from mounting substrate 200 or is toward mounting substrate 200.

For example, when the coefficient of thermal expansion of metal layer 30 is higher than the coefficient of thermal expansion of semiconductor layer 40, while being heated during reflow processing, semiconductor device 100 warps so as to curve projectingly in the direction in which the center of semiconductor device 100 is away from mounting substrate 200.

For example, when the coefficient of thermal expansion of metal layer 30 is lower than the coefficient of thermal expansion of semiconductor layer 40, while being heated during reflow processing, semiconductor device 100 warps so as to curve projectingly in the direction in which the center of semiconductor device 100 is toward mounting substrate 200.

Thus, in semiconductor module 1, semiconductor device 100 is face-down mounted above mounting substrate 200 in a state of being curved to project in the direction in which the center of semiconductor device 100 in the plan view of semiconductor device 100 is away from mounting substrate 200 or is toward mounting substrate 200.

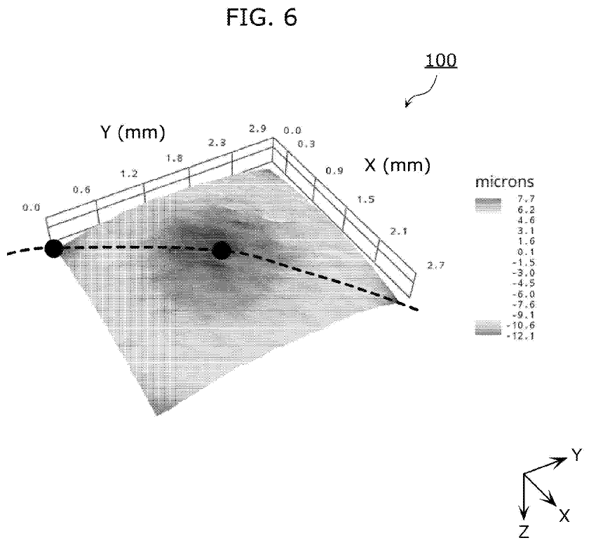

FIG. 6 is a perspective view schematically showing a state in which semiconductor device 100 has warped by being heated by reflow processing so that semiconductor device 100 is curved projectingly in the direction in which the center of semiconductor device 100 is away from mounting substrate 200.

As shown in FIG. 6, when semiconductor device 100 warps by being heated by reflow processing so that semiconductor device 100 is curved projectingly in the direction in which the center of semiconductor device 100 is away from mounting substrate 200, semiconductor device 100 warps concentrically from the center of semiconductor device 100 in the plan view of semiconductor device 100.

Also in this case, as shown in FIG. 6, the center of semiconductor device 100 in the plan view of semiconductor device 100 becomes the highest, and the four corners of semiconductor device 100 in the plan view of semiconductor device 100 become the lowest.

Similarly, when semiconductor device 100 warps by being heated by reflow processing so that semiconductor device 100 is curved projectingly in the direction in which the center of semiconductor device 100 is toward mounting substrate 200, semiconductor device 100 warps concentrically from the center of semiconductor device 100 in the plan view of semiconductor device 100.

Also in this case, the center of semiconductor device 100 in the plan view of semiconductor device 100 becomes the lowest, and the four corners of semiconductor device 100 in the plan view of semiconductor device 100 become the highest.

Note that in this Specification, the center of semiconductor device 100 in the plan view of semiconductor device 100 refers to the position of the intersection of the diagonals of semiconductor device 100 in the plan view of semiconductor device 100.

Furthermore, in this Specification, the center of semiconductor device 100 in the plan view of semiconductor device 100 may also be referred to simply as the center of semiconductor device 100.

In this Specification, the center of mounting substrate 200 in the plan view of mounting substrate 200 means the position in the plan view of mounting substrate 200 that coincides with the center of semiconductor device 100 in a state in which semiconductor device 100 is face-down mounted above mounting substrate 200.

Note that in this Specification, the center of mounting substrate 200 in the plan view of mounting substrate 200 may be referred to simply as the center of mounting substrate 200.

In this Specification, the center of pad 101 in the plan view of semiconductor device 100 refers to the position of the centroid of pad 101 in the plan view of semiconductor device 100.

Note that in this Specification, the center in the plan view refers to: for a structure rectangular in the plan view such as, for example, semiconductor device 100 as illustrated in FIG. 1, the intersection of the diagonals of the rectangle; for a structure that is obround in the plan view such as, for example, first source pad 111a to first source pad 111f and second source pad 121a to second source pad 121f as illustrated in FIG. 1, the intersection of the axis of symmetry along the longitudinal direction of the obround and the axis of symmetry along the transverse direction of the obround; for a structure that is circular in the plan view such as, for example, first gate pad 119 and second gate pad 129 as illustrated in FIG. 1, the center of the circle thereof; and for a structure that is elliptical in the plan view, the intersection of the major axis and the minor axis of the ellipse, for example.

However, when pad 101 straddles the center line extending in the first direction of semiconductor device 100 (the X-axis direction in FIG. 1) or the center line extending in the second direction thereof (the Y-axis direction in FIG. 1) (hereafter such pad 101 is also referred to as a “center line-straddling pad”) in the plan view of semiconductor device 100, that single center line-straddling pad is regarded as being configured of two pads 101, that is, one pad 101 on one side of the center line and one pad 101 on the other side of the center line, which are disposed continuously across that center line.

The centroid position of pad 101 on one side of the center line in the plan view of semiconductor device 100 is referred to as the center (hereinafter also referred to as “first center”) of pad 101 on the one side in the plan view of semiconductor device 100, and the centroid position of pad 101 on the other side of the center line in the plan view of semiconductor device 100 is referred to as the center (hereinafter also referred to as “second center”) of pad 101 on the other side in the plan view of semiconductor device 100.

That is, in this Specification, when a center line-straddling pad exists, that center line-straddling pad is regarded as being configured of two pads 101, that is, one pad 101 centered at the first center and one pad 101 centered at the second center.

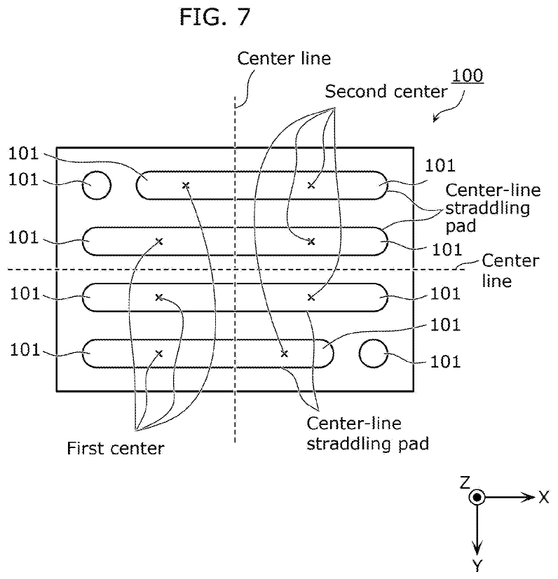

FIG. 7 is an example of a plan view of semiconductor device 100 when semiconductor device 100 includes center line-straddling pads.

As shown in FIG. 7, in this Specification, each of the center line-straddling pads is regarded as being configured of two pads 101, that is, one pad 101 centered at the first center and one pad 101 centered at the second center.

In this Specification, the “center” of land 201 in the plan view of mounting substrate 200 refers to the position of the centroid of land 201 in the plan view of mounting substrate 200.

However, in the plan view of mounting substrate 200, when land 201 straddles the center line extending in the first direction (the X-axis direction in FIG. 1) of semiconductor device 100 or the center line extending in the second direction thereof (the Y-axis direction in FIG. 1) (hereafter such land 201 is also referred to as a “center line-straddling land”) in a state in which semiconductor device 100 is face-down mounted above mounting substrate 200, that single center line-straddling land is regarded as being configured of two lands 201, that is, one land 201 on one side of the center line and one land 201 on the other side of the center line, which are disposed continuously across that center line.

The centroid position of land 201 on one side of the center line in the plan view of mounting substrate 200 is referred to as the center (hereinafter also referred to as “third center”) of land 201 on that one side in the plan view of mounting substrate 200, and the centroid position of land 201 on the other side of the center line in the plan view of mounting substrate 200 is referred to as the center (hereinafter also referred to as “fourth center”) of land 201 on the other side in the plan view of mounting substrate 200.

That is, in this Specification, when a center line-straddling land exists, that center line-straddling land is regarded as being configured of two lands 201, that is, one land 201 centered at the third center and one land 201 centered at the fourth center.

In this Specification, the distance from the center of semiconductor device 100 to pad 101 in the plan view of semiconductor device 100 means the distance from the center of semiconductor device 100 to the center of pad 101 in the plan view of semiconductor device 100.

Note that in this Specification, the distance from the center of semiconductor device 100 to pad 101 in the plan view of semiconductor device 100 may also be referred to simply as the distance from the center of semiconductor device 100 to pad 101.

In this Specification, the distance from the center of mounting substrate 200 to land 201 in the plan view of mounting substrate 200 means the distance from the center of mounting substrate 200 to the center of land 201 in the plan view of mounting substrate 200.

Note that in this Specification, the distance from the center of mounting substrate 200 to land 201 in the plan view of mounting substrate 200 may be referred to simply as the distance from the center of mounting substrate 200 to land 201.

In this Specification, diagonal length R of semiconductor device 100 refers to the length of the diagonal of semiconductor device 100 in the plan view of semiconductor device 100.

In this Specification, curvature magnitude a of semiconductor device 100 refers to: when semiconductor device 100 warps so as to curve projectingly in a direction in which the center of semiconductor device 100 is away from mounting substrate 200, the height difference between the highest position within the lower surface of semiconductor device 100 in a state of being face-down mounted above mounting substrate 200, or stated differently, the center of semiconductor device 100 in the plan view of semiconductor device 100 and the lowest position within the lower surface thereof, or stated differently, the four corners of semiconductor device 100 in the plan view of semiconductor device 100; and when semiconductor device 100 warps so as to curve projectingly in a direction in which the center of semiconductor device 100 is toward mounting substrate 200, the height difference between the lowest position within the lower surface of semiconductor device 100 in a state of being face-down mounted above mounting substrate 200, or stated differently, the center of semiconductor device 100 in the plan view of semiconductor device 100 and the highest position within the lower surface thereof, or stated differently, the four corners of semiconductor device 100 in the plan view of semiconductor device 100.

In other words, curvature magnitude a of semiconductor device 100 refers to the maximum warpage amount of semiconductor device 100.

In this Specification, reference radius r of semiconductor device 100 refers to, in a state in which semiconductor device 100 is face-down mounted above mounting substrate 200, the distance in the plan view of semiconductor device 100 from the center of semiconductor device 100 to the position at which the warpage amount of semiconductor device 100 becomes the average.

In this Specification, description is given assuming that reference radius r is calculated by either of the following two calculation methods.

Calculation Method 1: A simple method of calculating reference radius r, assuming that the warpage of semiconductor device 100 is a linear change in a cross-sectional view of semiconductor device 100.

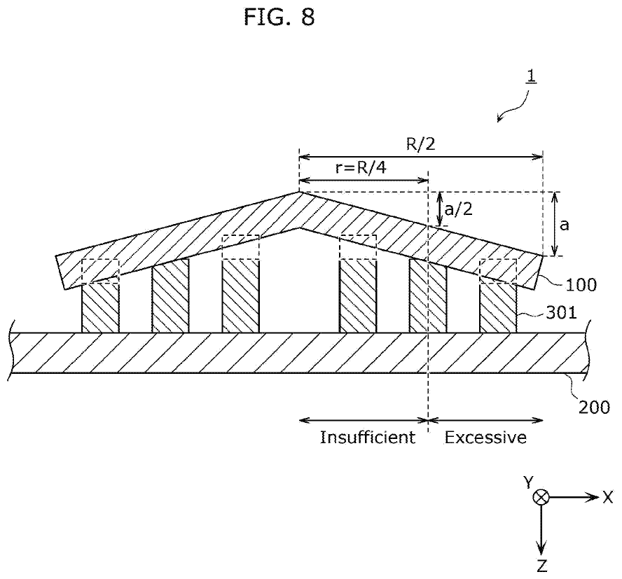

FIG. 8 is a schematic cross-sectional diagram showing a state of calculating reference radius r by Calculation Method 1.

FIG. 8 shows semiconductor device 100 as if its warpage of semiconductor device 100 were a linear change, yet this illustration is for the purpose of simply calculating reference radius r by assuming the warpage of semiconductor device 100 is a linear change, and does not imply that the actual warpage of semiconductor device 100 is necessarily a linear change.

As shown in FIG. 8, with Calculation Method 1, ¼ of diagonal length R, that is, the distance from the center of semiconductor device 100 to the position where the warpage amount of semiconductor device 100 is half (½) of curvature magnitude a, is calculated as reference radius r.

Thus, reference radius r is calculated by the following equation.

$$r = R / 4$$

Calculation Method 2: A method of calculating reference radius r by computing the weighted average of the distances from the center of semiconductor device 100 to pads 101, using the areas of pads 101 as the weight.

Thus, when with use of n mutually distinct values of k (k is an integer between 1 and n, inclusive), each of n pads 101 is denoted as k-th pad 101, the area of each of n pads 101 indexed by k in the plan view of semiconductor device 100 is denoted by P(k), and the distance from the center of semiconductor device 100 to the center of each of n pads 101 indexed by k in the plan view of semiconductor device 100 is denoted by D(k), reference radius r is calculated by the following equation.

$$r = \frac{{\sum }_{k = 1}^{n} D ( k ) \times P ( k )}{{\sum }_{k = 1}^{n} P ( k )} \qquad [ Math 4 ]$$

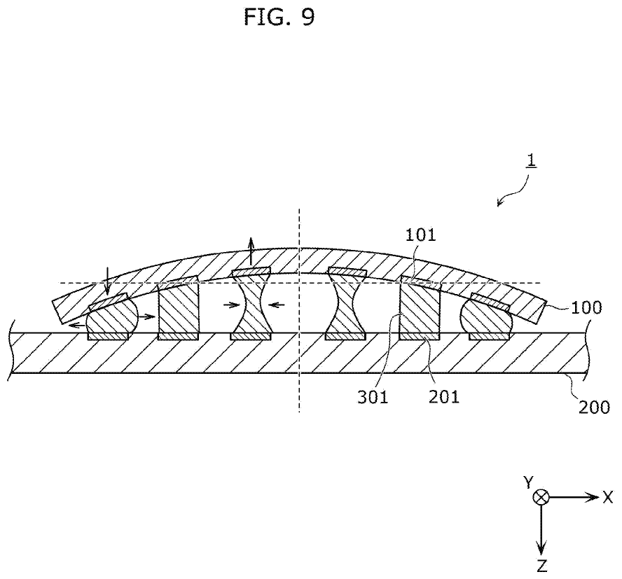

FIG. 9 is a schematic cross-sectional view showing an example of a cross section of semiconductor module 1 when semiconductor device 100 is mounted above mounting substrate 200 in a state in which semiconductor device 100 is curved projectingly in a direction in which the center of semiconductor device 100 is away from mounting substrate 200.

As shown in FIG. 9, when semiconductor device 100 is mounted above mounting substrate 200 in a state in which semiconductor device 100 is curved projectingly in a direction in which the center of semiconductor device 100 is away from mounting substrate 200, the farther pad 101 is from the center of semiconductor device 100, the closer pad 101 is to land 201, and the closer pad 101 is from the center of semiconductor device 100, the farther pad 101 is from land 201.

Thus, when semiconductor device 100 is mounted above mounting substrate 200 in a state in which semiconductor device 100 is curved projectingly in a direction in which the center of semiconductor device 100 is away from mounting substrate 200, Pa denotes the area in the plan view of semiconductor device 100 of, among n pads 101, the closest pad that is closest to the center of semiconductor device 100 in the plan view of semiconductor device 100, Pb denotes the area in the plan view of semiconductor device 100 of the farthest pad thereamong that is farthest therefrom, La denotes the area of the closest land corresponding to the closest pad among n lands 201 in the plan view of mounting substrate 200, and Lb denotes the area of the farthest land corresponding to the farthest pad thereamong in the plan view of mounting substrate 200, Pa/La may be less than 1 and Pb/Lb may be greater than 1, or Pa/La may be greater than 1 and Pb/Lb may be less than 1.

This inhibits the occurrence of a defect in which solder bonding material 301 is insufficient relative to the closest pad and a defect in which solder bonding material 301 protrudes from the farthest pad, or inhibits the occurrence of a defect in which solder bonding material 301 is insufficient relative to the closest land and a defect in which solder bonding material 301 protrudes from the farthest land.

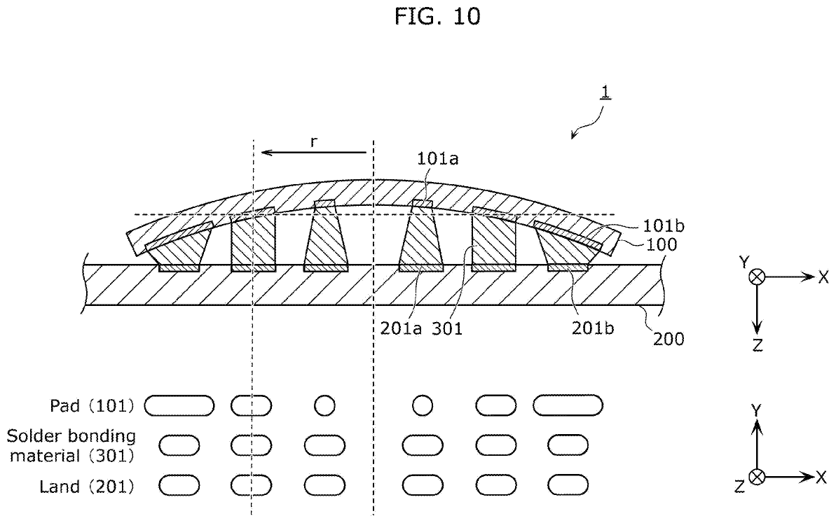

FIG. 10 is a schematic diagram showing examples of the positions and shapes of pads 101, the positions and shapes of lands 201, and the positions and shapes of solder bonding material 301 in semiconductor module 1 in which the conditions that Pa/La is less than 1 and Pb/Lb is greater than 1 are satisfied, when semiconductor device 100 is mounted above mounting substrate 200 in a state in which semiconductor device 100 is curved projectingly in a direction in which the center of semiconductor device 100 is away from mounting substrate 200.

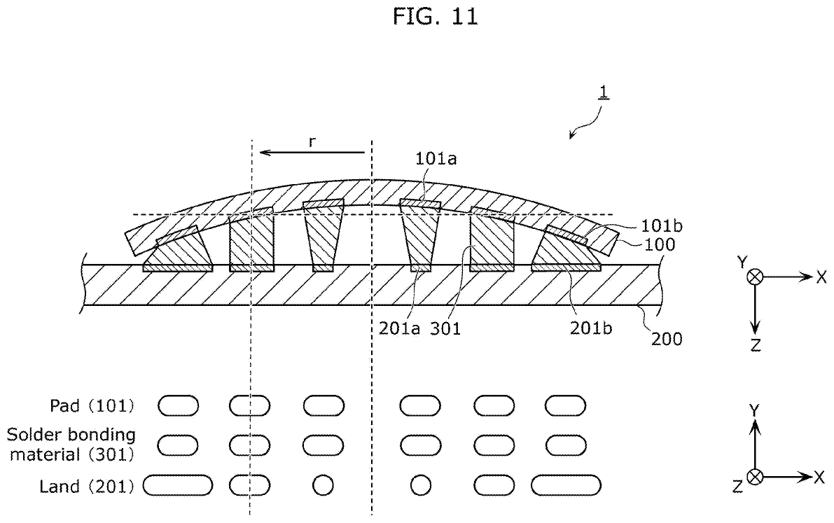

FIG. 11 is a schematic diagram showing examples of the positions and shapes of pads 101, the positions and shapes of lands 201, and the positions and shapes of solder bonding material 301 in semiconductor module 1 in which the conditions that Pa/La is greater than 1 and Pb/Lb is less than 1 are satisfied, when semiconductor device 100 is mounted above mounting substrate 200 in a state in which semiconductor device 100 is curved projectingly in a direction in which the center of semiconductor device 100 is away from mounting substrate 200.

Note that the positions and shapes of solder bonding material 301 in the lower illustrations of FIGS. 10 and 11 show examples of the positions and shapes in the state prior to joining pads 101 and lands 201 in one-to-one correspondence.

The upper illustrations of FIGS. 10 and 11 are cross-sectional views schematically showing examples of cross sections of semiconductor module 1, and the lower illustrations are plan views schematically showing examples of pads 101, lands 201, and solder bonding material 301.

As shown in FIG. 10, for example, conditions that Pa/La is less than 1 and Pb/Lb is greater than 1 may be satisfied by making area Pa of closest pad 101a smaller than area La of closest land 201a and making area Pb of farthest pad 101b larger than area Lb of farthest land 201b.

This inhibits occurrence of a defect in which solder bonding material 301 is insufficient relative to closest pad 101a and a defect in which solder bonding material 301 protrudes from farthest pad 101b.

Alternatively, as shown in FIG. 11, for example, conditions that Pa/La is greater than 1 and Pb/Lb is less than 1 may be satisfied by making area La of closest land 201a smaller than area Pa of closest pad 101a and making area Lb of farthest land 201b larger than area Pb of farthest pad 101b.

This inhibits occurrence of a defect in which solder bonding material 301 is insufficient relative to closest land 201a and a defect in which solder bonding material 301 protrudes from farthest land 201b.

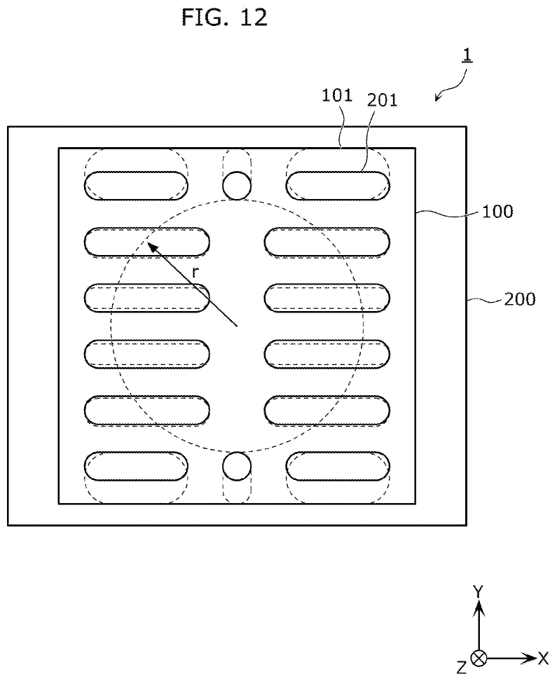

FIG. 12 is a plan view of semiconductor module 1 schematically showing examples of the shapes of n pads 101 and the shapes of n lands 201 in semiconductor module 1 having a configuration shown in FIG. 10, where area Pa of closest pad 101a is smaller than area La of closest land 201a and area Pb of farthest pad 101b is larger than area Lb of farthest land 201b.

In FIG. 12, n pads 101 are indicated by broken lines as if they were visible from the upper surface of semiconductor module 1, and n lands 201 are indicated by solid lines as if they were visible from the upper surface of semiconductor module 1, but nevertheless, in reality these cannot be directly seen from the upper surface of semiconductor module 1.

Note that in FIG. 12, the ratio between the size defined by the outline of semiconductor device 100 and the size defined by the outline of mounting substrate 200 in the plan view of semiconductor module 1 does not reflect the actual ratio. For example, the actual ratio of the size defined by the outline of mounting substrate 200 to the size defined by the outline of semiconductor device 100 in the plan view of semiconductor module 1 may be higher than the ratio shown by the example in FIG. 12.

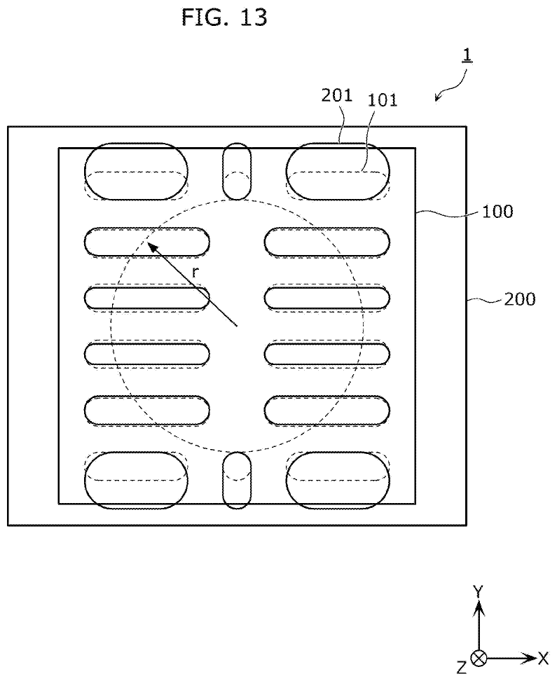

FIG. 13 is a plan view of semiconductor module 1 schematically showing examples of the shapes of n pads 101 and the shapes of n lands 201 in semiconductor module 1 having a configuration shown in FIG. 11, where area La of closest land 201a is smaller than area Pa of closest pad 101a and area Lb of farthest land 201b is larger than area Pb of farthest pad 101b.

In FIG. 13, n pads 101 are indicated by broken lines as if they were visible from the upper surface of semiconductor module 1, and n lands 201 are indicated by solid lines as if they were visible from the upper surface of semiconductor module 1, but nevertheless, in reality these cannot be directly seen from the upper surface of semiconductor module 1.

Note that in FIG. 13, the ratio between the size defined by the outline of semiconductor device 100 and the size defined by the outline of mounting substrate 200 in the plan view of semiconductor module 1 does not reflect the actual ratio. For example, the actual ratio of the size defined by the outline of mounting substrate 200 to the size defined by the outline of semiconductor device 100 in the plan view of semiconductor module 1 may be higher than the ratio shown by the example in FIG. 13.

As illustrated in FIG. 9, when semiconductor device 100 is mounted above mounting substrate 200 in a state in which semiconductor device 100 is curved projectingly in a direction in which the center of semiconductor device 100 is away from mounting substrate 200, as shown further in FIGS. 10 and 11, with use of n values of k (k is an integer between 1 and n, inclusive), each of n pads 101 is denoted as k-th pad 101, each of n lands 201 corresponding to n pads 101 indexed by k is denoted as k-th land 201, the area in the plan view of semiconductor device 100 of each of n pads 101 indexed by k is denoted by P(k), and the area in the plan view of mounting substrate 200 of each of n lands 201 indexed by k is denoted by L(k), P(k)/L(k) may monotonically increase or monotonically decrease with the distance from the center of semiconductor device 100 to each of n pads 101 indexed by k in the plan view of semiconductor device 100.

This further inhibits the occurrence of defects related to solder bonding material 301.

Note that in this Specification, monotonically increasing means a monotonically non-decreasing function. Thus, a monotonically non-decreasing function means a function f(x) such that x1<x2 implies f(x1)≤f(x2).

Furthermore, in this Specification, monotonically decreasing means a monotonically non-increasing function. Thus, a monotonically non-increasing function means a function f(x) such that x1<x2 implies f(x1)≥f(x2).

As shown in FIG. 10, when semiconductor device 100 is mounted above mounting substrate 200 in a state in which semiconductor device 100 is curved projectingly in a direction in which the center of semiconductor device 100 is away from mounting substrate 200, in semiconductor module 1 having a configuration in which area Pa of closest pad 101a is smaller than area La of closest land 201a and area Pb of farthest pad 101b is larger than area Lb of farthest land 201b, when D(k) denotes the distance from the center of semiconductor device 100 in the plan view of semiconductor device 100 to the center of each of n pads 101 indexed by k, for each of one or more inner pads, among n pads 101 indexed by k, which are located inside the circle centered at the center of semiconductor device 100 in the plan view of semiconductor device 100 and having, as its radius, reference radius r determined by

$$r = \frac{{\sum }_{k = 1}^{n} D ( k ) \times P ( k )}{{\sum }_{k = 1}^{n} P ( k )} \qquad [ Math 5 ]$$

or reference radius r e ermined by ¼ of the length of the diagonal of semiconductor device 100 (i.e., ¼ of the diagonal length of semiconductor device 100) in the plan view of semiconductor device 100, P(k)/L(k) may be less than 1, and for each of one or more outer pads, among n pads indexed by k, which are located outside the above circle in the plan view of semiconductor device 100, P(k)/L(k) may be greater than 1.

This further inhibits the occurrence of defects related to solder bonding material 301.

As shown in FIG. 11, when semiconductor device 100 is mounted above mounting substrate 200 in a state in which semiconductor device 100 is curved projectingly in a direction in which the center of semiconductor device 100 is away from mounting substrate 200, in semiconductor module 1 having a configuration in which area La of closest land 201a is smaller than area Pa of closest pad 101a and area Lb of farthest land 201b is larger than area Pb of farthest pad 101b, for each of one or more inner pads, among n pads 101 indexed by k, which are located inside the circle centered at the center of semiconductor device 100 in the plan view of semiconductor device 100 and having, as its radius, reference radius r determined by

$$r = \frac{{\sum }_{k = 1}^{n} D ( k ) \times P ( k )}{{\sum }_{k = 1}^{n} P ( k )} \qquad [ Math 6 ]$$

or reference radius r determined by ¼ of the length of the diagonal of semiconductor device 100 (i.e., ¼ of the diagonal length of semiconductor device 100) in the plan view of semiconductor device 100, P(k)/L(k) may be greater than 1, and for each of one or more outer pads, among the n pads indexed by k, which are located outside the above circle, P(k)/L(k) may be less than 1.

This further inhibits the occurrence of defects related to solder bonding material 301.

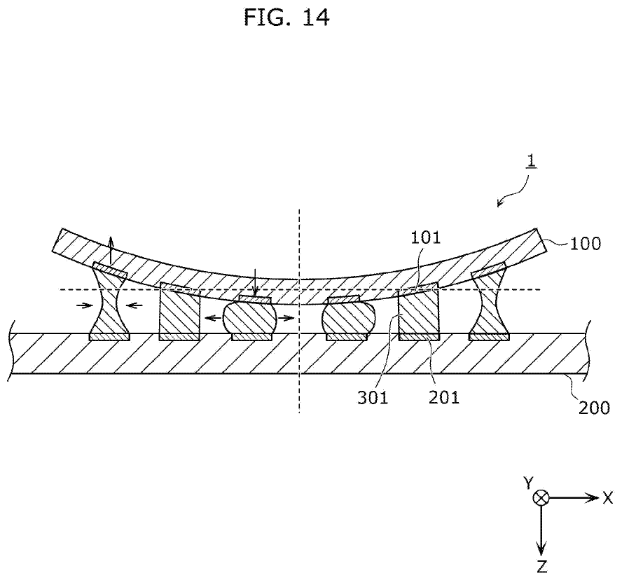

FIG. 14 is a cross-sectional view schematically showing an example of a cross section of semiconductor module 1 when semiconductor device 100 is mounted above mounting substrate 200 in a state in which semiconductor device 100 is curved projectingly in a direction in which the center of semiconductor device 100 is toward mounting substrate 200.

As shown in FIG. 14, when semiconductor device 100 is mounted above mounting substrate 200 in a state in which semiconductor device 100 is curved projectingly in a direction in which the center of semiconductor device 100 is toward mounting substrate 200, the closer pad 101 is from the center of semiconductor device 100, the closer pad 101 is to land 201, and the farther pad 101 is from the center of semiconductor device 100, the farther pad 101 is from land 201.

Thus, in a case where semiconductor device 100 is mounted above mounting substrate 200 in a state in which semiconductor device 100 is curved projectingly in a direction in which the center of semiconductor device 100 is toward mounting substrate 200, when Pa denotes the area in the plan view of semiconductor device 100 of, the closest pad that is closest to the center of semiconductor device 100 in the plan view of semiconductor device 100 among n pads 101, Pb denotes the area in the plan view of semiconductor device 100 of the farthest pad thereamong that is farthest therefrom, La denotes the area of the closest land corresponding to the closest pad among n lands 201 in the plan view of mounting substrate 200, and Lb denotes the area of the farthest land corresponding to the farthest pad thereamong in the plan view of mounting substrate 200, Pa/La may be greater than 1 and Pb/Lb may be less than 1, or Pa/La may be less than 1 and Pb/Lb may be greater than 1.

This inhibits the occurrence of a defect in which solder bonding material 301 protrudes from the closest pad and a defect in which solder bonding material 301 is insufficient relative to the farthest pad, or inhibits the occurrence of a defect in which solder bonding material 301 protrudes from the closest land and a defect in which solder bonding material 301 is insufficient relative to the farthest land.

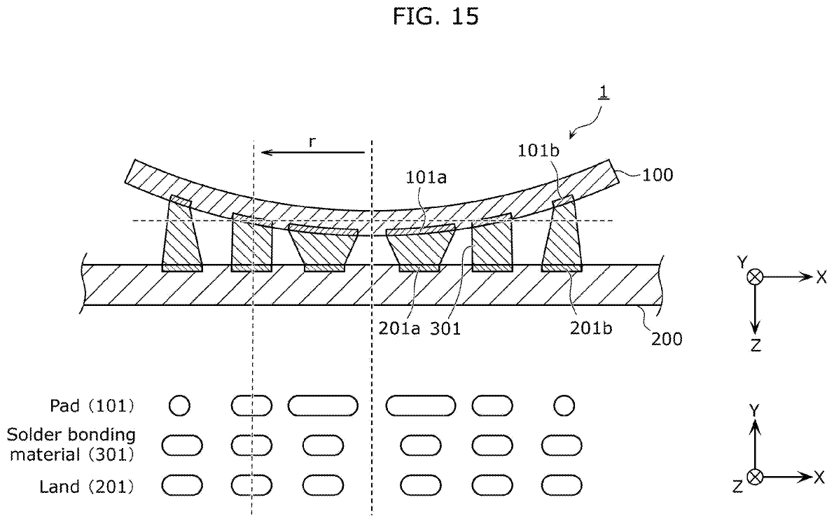

FIG. 15 is a schematic diagram showing examples of the positions and shapes of pads 101, the positions and shapes of lands 201, and the positions and shapes of solder bonding material 301 in semiconductor module 1 in which the conditions that Pa/La is greater than 1 and Pb/Lb is less than 1 are satisfied, when semiconductor device 100 is mounted above mounting substrate 200 in a state in which semiconductor device 100 is curved projectingly in a direction in which the center of semiconductor device 100 is toward mounting substrate 200.

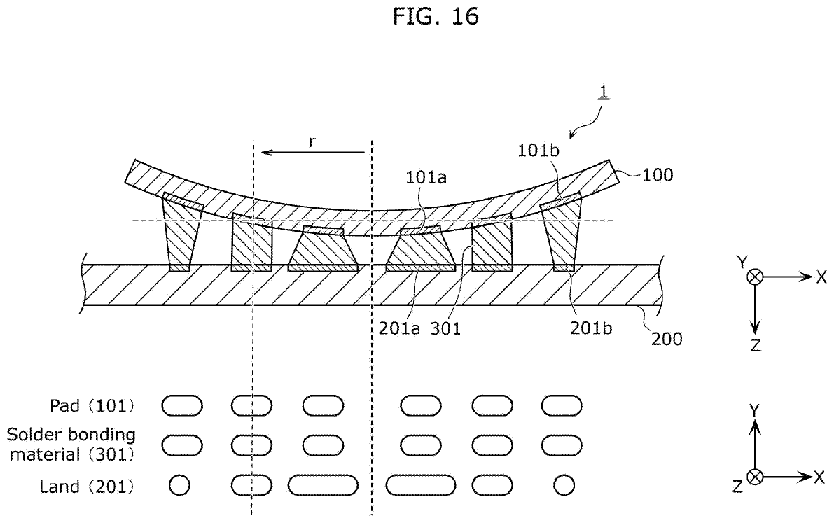

FIG. 16 is a schematic diagram showing examples of the positions and shapes of pads 101, the positions and shapes of lands 201, and the positions and shapes of solder bonding material 301 in semiconductor module 1 in which the conditions that Pa/La is less than 1 and Pb/Lb is greater than 1 are satisfied, when semiconductor device 100 is mounted above mounting substrate 200 in a state in which semiconductor device 100 is curved projectingly in a direction in which the center of semiconductor device 100 is toward mounting substrate 200.

The upper illustrations of FIGS. 15 and 16 are cross-sectional views schematically showing examples of cross sections of semiconductor module 1, and the lower illustrations are plan views schematically showing examples of pads 101, lands 201, and solder bonding material 301.

As shown in FIG. 15, for example, conditions that Pa/La is greater than 1 and Pb/Lb is less than 1 may be satisfied by making area Pa of closest pad 101a larger than area La of closest land 201a and making area Pb of farthest pad 101b smaller than area Lb of farthest land 201b.

This inhibits occurrence of a defect in which solder bonding material 301 protrudes from closest pad 101a and a defect in which solder bonding material 301 is insufficient with respect to farthest pad 101b.

Alternatively, as shown in FIG. 16, for example, conditions that Pa/La is less than 1 and Pb/Lb is greater than 1 may be satisfied by making area La of closest land 201a larger than area Pa of closest pad 101a and making area Lb of farthest land 201b smaller than area Pb of farthest pad 101b.

This inhibits occurrence of a defect in which solder bonding material 301 protrudes from the closest land and a defect in which solder bonding material 301 is insufficient with respect to the farthest land.

In a case where as shown in FIG. 14, semiconductor device 100 is mounted above mounting substrate 200 in a state in which semiconductor device 100 is curved projectingly in a direction in which the center of semiconductor device 100 is toward mounting substrate 200, when as shown further in FIGS. 15 and 16, with use of n values of k, each of n pads 101 is denoted as k-th pad 101, each of n lands 201 corresponding to n pads 101 indexed by k is denoted as k-th land 201, the area in the plan view of semiconductor device 100 of each of n pads 101 indexed by k is denoted by P(k), and the area in the plan view of mounting substrate 200 of each of n lands 201 indexed by k is denoted by L(k), P(k)/L(k) may monotonically increase or monotonically decrease with the distance from the center of semiconductor device 100 to each of n pads 101 indexed by k in the plan view of semiconductor device 100.

When semiconductor device 100 is mounted above mounting substrate 200 in a state in which semiconductor device 100 is curved projectingly in a direction in which the center of semiconductor device 100 is toward mounting substrate 200 as shown in FIG. 16, in semiconductor module 1 having a configuration in which area Pa of closest pad 101a is smaller than area La of closest land 201a and area Pb of farthest pad 101b is larger than area Lb of farthest land 201b, when D(k) denotes the distance from the center of semiconductor device 100 in the plan view of semiconductor device 100 to the center of each of n pads 101 indexed by k, for each of one or more inner pads, among n pads 101 indexed by k, which are located inside the circle centered at the center of semiconductor device 100 in the plan view of semiconductor device 100 and having, as its radius, reference radius r determined by

$$r = \frac{{\sum }_{k = 1}^{n} D ( k ) \times P ( k )}{{\sum }_{k = 1}^{n} P ( k )} \qquad [ Math 7 ]$$

or reference radius r determined by ¼ of the length of the diagonal of semiconductor device 100 (i.e., ¼ of the diagonal length of semiconductor device 100), P(k)/L(k) may be less than 1, and for each of one or more outer pads, among n pads indexed by k, which are located outside the above circle in the plan view of semiconductor device 100, P(k)/L(k) may be greater than 1.

This further inhibits the occurrence of defects related to solder bonding material 301.

When semiconductor device 100 is mounted above mounting substrate 200 in a state in which semiconductor device 100 is curved projectingly in a direction in which the center of semiconductor device 100 is toward mounting substrate 200 as shown in FIG. 15, in semiconductor module 1 having a configuration in which area La of closest land 201a is smaller than area Pa of closest pad 101a and area Lb of farthest land 201b is larger than area Pb of farthest pad 101b, for each of one or more inner pads, among n pads 101 indexed by k, which are located inside the circle centered at the center of semiconductor device 100 in the plan view of semiconductor device 100 and having, as its radius, reference radius r determined by

$$r = \frac{{\sum }_{k = 1}^{n} D ( k ) \times P ( k )}{{\sum }_{k = 1}^{n} P ( k )} \qquad [ Math 8 ]$$

or reference radius r determined by ¼ of the length of the diagonal of semiconductor device 100 (i.e., ¼ of the diagonal length of semiconductor device 100) in the plan view of semiconductor device 100, P(k)/L(k) may be greater than 1, and for each of one or more outer pads located outside the above circle among n pads indexed by k, P(k)/L(k) may be less than 1.

This further inhibits the occurrence of defects related to solder bonding material 301.

### <Method for Manufacturing Semiconductor Module>

Below, a method for manufacturing semiconductor module 1 having the above configuration will be described.

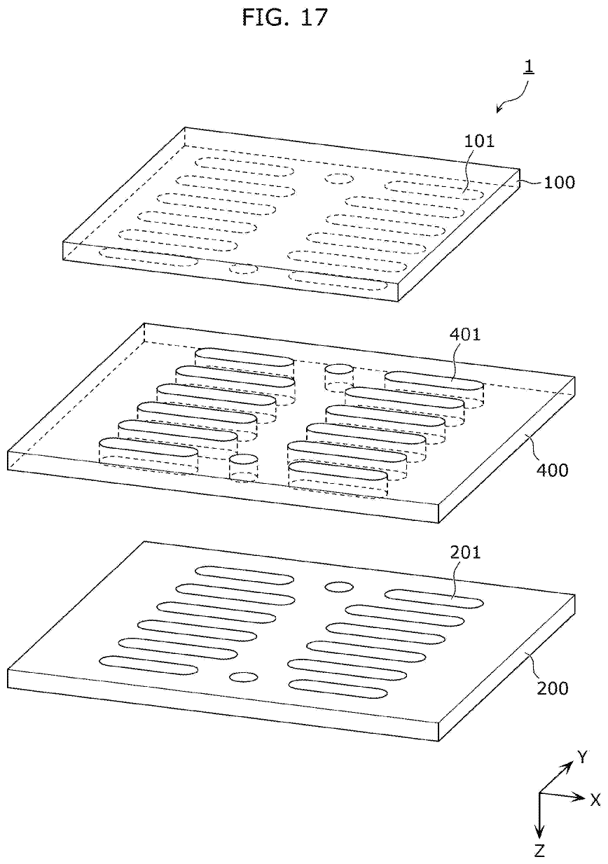

Semiconductor module 1 having the above configuration is manufactured by semiconductor module manufacturing processing in which semiconductor device 100 is face-down mounted above mounting substrate 200 using stencil 400 described later (see FIG. 17 described later) to manufacture semiconductor module 1.

FIG. 17 is a perspective view illustrating an example of a structure of stencil 400. In FIG. 17, perspective views of semiconductor device 100 and mounting substrate 200 are also illustrated in order that n apertures 401 included in stencil 400, n pads 101 included in semiconductor device 100, and n lands 201 included in mounting substrate 200 are shown as corresponding one-to-one.

In FIG. 17, n pads 101 are shown as if they were visible through semiconductor device 100, but in reality, they cannot be directly viewed through semiconductor device 100.

Note that in FIG. 17, the ratio among the size defined by the outline of semiconductor device 100, the size defined by the outline of mounting substrate 200, and the size defined by the outline of stencil 400 in the plan view of semiconductor module 1 does not reflect the actual ratio. For example, the actual ratio of the size defined by the outline of stencil 400 to the size defined by the outline of semiconductor device 100 in the plan view of semiconductor module 1 may be higher than the ratio shown in FIG. 17, and the actual ratio of the size defined by the outline of mounting substrate 200 to the size defined by the outline of stencil 400 in the plan view of semiconductor module 1 may be higher than the ratio shown in FIG. 17.

As shown in FIG. 17, stencil 400 includes n apertures 401 that correspond one-to-one to the n pads included in semiconductor device 100.

Each of n apertures 401 is an aperture for providing solder bonding material 301 that joins one of n pads 101 corresponding to that aperture 401 and one of n lands 201 corresponding to that aperture 401, above that one land 201.

Stencil 400 is, for example, made of metal, and its thickness is, for example, 80 μm.

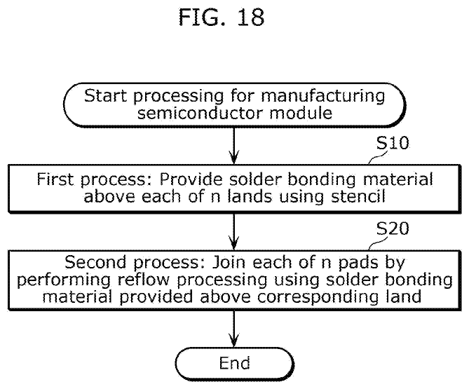

FIG. 18 is a flowchart of the semiconductor module manufacturing processing.

As shown in FIG. 18, the semiconductor module manufacturing processing includes a first process (step S10) and a second process (step S20), in this order.

When the semiconductor module manufacturing processing starts, the first process is performed first.

The first process is a process of providing, using stencil 400, solder bonding material 301 above n lands 201.

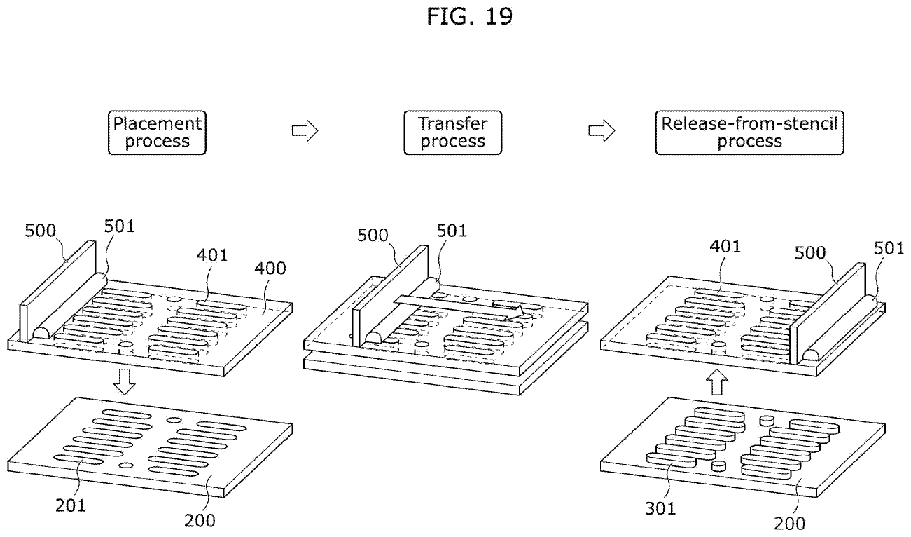

FIG. 19 is a schematic diagram showing the state in which the first process is being performed.

As shown in FIG. 19, the first process is a process of performing, in this order, a placement process, a transfer process, and a release-from-stencil process.

Note that in FIG. 19, the ratio between the size defined by the outline of stencil 400 in the plan view of stencil 400 and the size defined by the outline of mounting substrate 200 in the plan view of mounting substrate 200 does not reflect the actual ratio. For example, the actual ratio of the size defined by the outline of mounting substrate 200 in the plan view of mounting substrate 200 to the size defined by the outline of stencil 400 in the plan view of stencil 400 may be higher than the ratio shown by the example in FIG. 19.

The placement process is a process of placing stencil 400 at a predetermined position on the upper surface of mounting substrate 200.

At this time, solder joining paste 501 in an amount sufficiently greater than the total volume of n deposits of solder bonding material 301 is placed on the upper surface of stencil 400.

The transfer process is a process of providing n deposits of solder bonding material 301 above n lands 201 included in mounting substrate 200 by sliding squeegee 500 across the upper surface of stencil 400 to fill the inside of n apertures 401 with solder joining paste 501.

The release-from-stencil process is a process of releasing stencil 400 from the upper surface of mounting substrate 200.

Returning to FIG. 18, the description of the semiconductor module manufacturing processing continues.

When the first process is completed, the second process is performed next.

The second process is a process of joining, by performing reflow processing, each of n pads 101 to one of n lands 201 corresponding to that pad 101, using solder bonding material 301 provided above that land 201 by performing the first process described above.

The reflow processing is performed with semiconductor device 100 being placed face-down above mounting substrate 200 in such a manner that n deposits of solder bonding material 301 provided above n lands 201 and n pads 101 overlap one-to-one in the plan view of mounting substrate 200.

When the second process is completed, the semiconductor module manufacturing processing ends.

Semiconductor module 1 manufactured by performing the above semiconductor module manufacturing processing includes, as described above, semiconductor device 100 mounted above mounting substrate 200 in a state in which semiconductor device 100 is curved projectingly in a direction in which the center of semiconductor device 100 is away from mounting substrate 200 or is toward mounting substrate 200.

Thus, in a case where semiconductor device 100 is mounted above mounting substrate 200 in a state in which semiconductor device 100 is curved projectingly in a direction in which the center of semiconductor device 100 is away from mounting substrate 200 as shown in FIG. 9, when Pa denotes the area in the plan view of semiconductor device 100 of the closest pad, among n pads 101, which is closest to the center of semiconductor device 100 in the plan view of semiconductor device 100, Pb denotes the area in the plan view of semiconductor device 100 of the farthest pad thereamong, which is farthest therefrom, La denotes the area in the plan view of mounting substrate 200 of the closest land corresponding to the closest pad among n lands, Lb denotes the area in the plan view of mounting substrate 200 of the farthest land corresponding to the farthest pad thereamong, Sa denotes the area in the plan view of stencil 400 of the closest aperture corresponding to the closest pad among n apertures 401, and Sb denotes the area in the plan view of stencil 400 of the farthest aperture corresponding to the farthest pad thereamong, Sa may be larger than each of Pa and La, and/or Sb may be smaller than each of Pb and Lb.

With this, (1) the amount of solder bonding material provided above the closest land with respect to area Pa of the closest pad and area La of the closest land can be made relatively large, and/or (2) the amount of solder bonding material provided above the farthest land with respect to area Pb of the farthest pad and area Lb of the farthest land can be made relatively small.

Thus, it is possible to manufacture semiconductor module 1 in which (1) the occurrence of a defect in which solder bonding material 301 is insufficient relative to the closest pad and a defect in which solder bonding material 301 is insufficient relative to the closest land are inhibited, and/or (2) the occurrence of a defect in which solder bonding material 301 protrudes from the farthest pad and a defect in which solder bonding material 301 protrudes from the farthest land are inhibited.

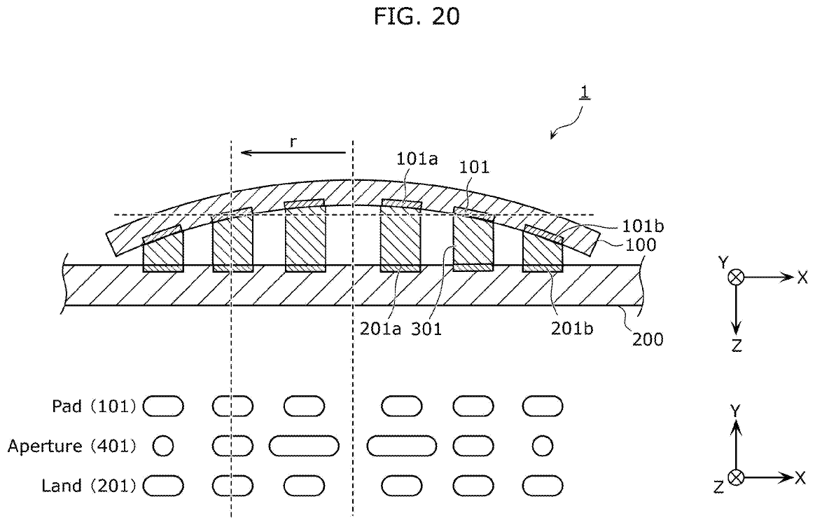

FIG. 20 is a schematic diagram showing examples of the positions and shapes of pads 101, the positions and shapes of lands 201, and the positions and shapes of apertures 401 in semiconductor module 1 manufactured using stencil 400 satisfying the condition that Sa is larger than each of Pa and La and/or Sb is smaller than each of Pb and Lb, when manufacturing semiconductor module 1 in which semiconductor device 100 is mounted above mounting substrate 200 in a state in which semiconductor device 100 is curved projectingly in a direction in which the center of semiconductor device 100 is away from mounting substrate 200, as shown in FIG. 9.

The upper illustration of FIG. 20 is a cross-sectional view schematically showing an example of a cross section of semiconductor module 1 manufactured by performing the semiconductor module manufacturing processing, and the lower illustration is a plan view schematically showing examples of pads 101, lands 201, and apertures 401.

As shown in FIG. 20, by manufacturing semiconductor module 1 using stencil 400 in which Sa is larger than each of Pa and La, the amount of solder bonding material 301 provided above closest land 201a may be made relatively large with respect to area Pa of closest pad 101a and area La of closest land 201a.

Accordingly, it is possible to manufacture semiconductor module 1 in which the occurrence of a defect in which solder bonding material 301 is insufficient relative to closest pad 101a and a defect in which solder bonding material 301 is insufficient relative to closest land 201a are inhibited.

Alternatively, as shown in FIG. 20, by manufacturing semiconductor module 1 using stencil 400 in which Sb is smaller than each of Pb and Lb, the amount of solder bonding material 301 provided above farthest land 201b may be made relatively small with respect to area Pb of farthest pad 101b and area Lb of farthest land 201b.

Accordingly, it is possible to manufacture semiconductor module 1 in which the occurrence of a defect in which solder bonding material 301 protrudes from farthest pad 101b and a defect in which solder bonding material 301 protrudes from farthest land 201b are inhibited.

In a case where semiconductor device 100 is mounted above mounting substrate 200 in a state in which semiconductor device 100 is curved projectingly in a direction in which the center of semiconductor device 100 is away from mounting substrate 200 as illustrated in FIG. 9, when with use of mutually distinct n values of k (k is an integer between 1 and n, inclusive), each of n pads 101 is denoted as k-th pad 101, each of n lands 201 corresponding to n pads 101 indexed by k is denoted as k-th land 201, each of n apertures 401 corresponding to n pads 101 indexed by k is denoted as k-th aperture 401, the area in the plan view of semiconductor device 100 of each of n pads 101 indexed by k is denoted by P(k), the area in the plan view of mounting substrate 200 of each of n lands 201 indexed by k is denoted by L(k), the area of each of n apertures 401 indexed by k in the plan view of stencil 400 is denoted by S(k), and the distance from the center of semiconductor device 100 in the plan view of semiconductor device 100 to the center of each of n pads 101 indexed by k is denoted by D(k), for each of one or more inner pads, among n pads 101 indexed by k, which are located inside the circle centered at the center of semiconductor device 100 in the plan view of semiconductor device 100 and having a radius denoted by r determined by

$$r = \frac{{\sum }_{k = 1}^{n} D ( k ) \times P ( k )}{{\sum }_{k = 1}^{n} P ( k )} \qquad [ Math 9 ]$$

or r determined by ¼ of the length of the diagonal of semiconductor device 100 in the plan view of semiconductor device 100, S(k) may be larger than each of P(k) and L(k), and/or for each of one or more outer pads thereamong located outside the above circle in the plan view of semiconductor device 100, S(k) may be smaller than each of P(k) and L(k), as shown in FIG. 20.

Accordingly, it is possible to manufacture semiconductor module 1 in which the occurrence of defects related to solder bonding material 301 is further inhibited.

When semiconductor device 100 is mounted above mounting substrate 200 in a state in which semiconductor device 100 is curved projectingly in a direction in which the center of semiconductor device 100 is away from mounting substrate 200 as shown in FIG. 9, for each of the inner pads, S(k)/P(k) may be greater than 1, and for each of the outer pads, S(k)/P(k) may be less than 1, as shown in FIG. 20.

Accordingly, it is possible to manufacture semiconductor module 1 in which the occurrence of defects related to solder bonding material 301 is further inhibited.

When semiconductor device 100 is mounted above mounting substrate 200 in a state in which semiconductor device 100 is curved projectingly in a direction in which the center of semiconductor device 100 is away from mounting substrate 200 as shown in FIG. 9, for each of the inner pads, S(k)/L(k) may be greater than 1, and for each of the outer pads, S(k)/L(k) may be less than 1, as shown in FIG. 20.

Accordingly, it is possible to manufacture semiconductor module 1 in which the occurrence of defects related to solder bonding material 301 is further inhibited.

Furthermore, in a case where semiconductor device 100 is mounted above mounting substrate 200 in a state in which semiconductor device 100 is curved projectingly in a direction in which the center of semiconductor device 100 is toward mounting substrate 200 as shown in FIG. 14, Pa denotes the area in the plan view of semiconductor device 100 of the closest pad that is closest to the center of semiconductor device 100 in the plan view of semiconductor device 100 among n pads 101, Pb denotes the area in the plan view of semiconductor device 100 of the farthest pad thereamong that is farthest therefrom, La denotes the area in the plan view of mounting substrate 200 of the closest land corresponding to the closest pad among n lands 201, Lb denotes the area in the plan view of mounting substrate 200 of the farthest land corresponding to the farthest pad thereamong, Sa denotes the area in the plan view of stencil 400 of the closest aperture corresponding to the closest pad among n apertures 401, and Sb denotes the area in the plan view of stencil 400 of the farthest aperture corresponding to the farthest pad, Sa may be smaller than each of Pa and La, and/or Sb may be larger than each of Pb and Lb.

With this, (1) the amount of solder bonding material provided above the closest land with respect to area Pa of the closest pad and area La of the closest land can be made relatively small, and/or (2) the amount of solder bonding material provided above the farthest land with respect to area Pb of the farthest pad and area Lb of the farthest land can be made relatively large.

Thus, it is possible to manufacture semiconductor module 1 in which (1) the occurrence of a defect in which solder bonding material 301 protrudes from the closest pad and a defect in which solder bonding material 301 protrudes from the closest land are inhibited, and/or (2) the occurrence of a defect in which solder bonding material 301 is insufficient relative to the farthest pad and a defect in which solder bonding material 301 is insufficient relative to the farthest land are inhibited.

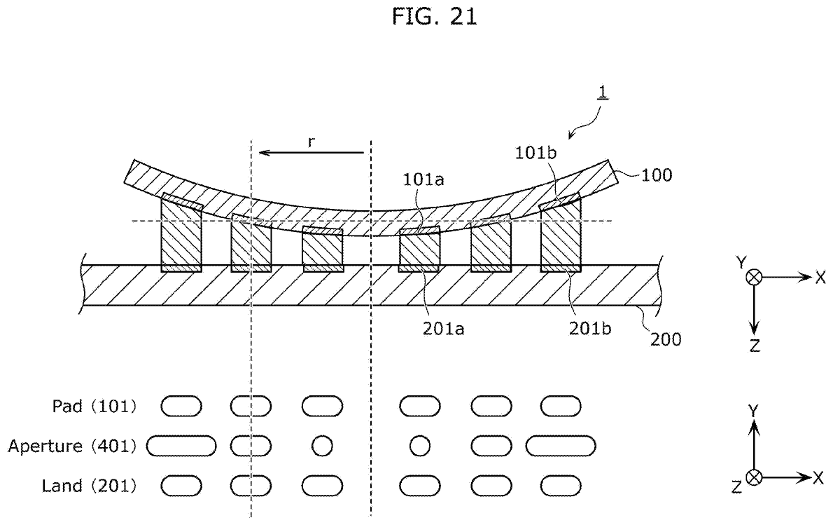

FIG. 21 is a schematic diagram showing examples of the positions and shapes of pads 101, the positions and shapes of lands 201, and the positions and shapes of apertures 401 in semiconductor module 1 manufactured using stencil 400 satisfying a condition that Sa is smaller than each of Pa and La, and/or Sb is larger than each of Pb and Lb, when manufacturing semiconductor module 1 in which semiconductor device 100 is mounted above mounting substrate 200 in a state in which semiconductor device 100 is curved projectingly in a direction in which the center of semiconductor device 100 is toward mounting substrate 200, as shown in FIG. 14.

The upper illustration of FIG. 21 is a cross-sectional view schematically showing an example of a cross section of semiconductor module 1 manufactured by performing the semiconductor module manufacturing processing, and the lower illustration is a plan view schematically showing examples of pads 101, lands 201, and apertures 401.

As shown in FIG. 21, by manufacturing semiconductor module 1 using stencil 400 in which Sa is smaller than each of Pa and La, the amount of solder bonding material 301 provided above closest land 201a may be made relatively small with respect to area Pa of closest pad 101a and area La of closest land 201a.

Accordingly, it is possible to manufacture semiconductor module 1 in which the occurrence of a defect in which solder bonding material 301 protrudes from closest pad 101a and a defect in which solder bonding material 301 protrudes from closest land 201a are inhibited.

Furthermore, as shown in FIG. 21, by manufacturing semiconductor module 1 using stencil 400 in which Sb is larger than each of Pb and Lb, the amount of solder bonding material 301 provided above farthest land 201b may be made relatively large with respect to area Pb of farthest pad 101b and area Lb of farthest land 201b.

Accordingly, it is possible to manufacture semiconductor module 1 in which the occurrence of a defect in which solder bonding material 301 is insufficient relative to farthest pad 101b and a defect in which solder bonding material 301 is insufficient relative to farthest land 201b are inhibited.

By the way, semiconductor devices that are commercially distributed typically come with product datasheets. In the product datasheet, in addition to the pad pattern of the semiconductor device, recommended land patterns and recommended stencil patterns for face-down mounting of the semiconductor device above a mounting substrate are sometimes included. In the mounting using a stencil as described in the semiconductor module manufacturing method of the present disclosure, the features described herein can be understood by correlating them with the recommended stencil pattern included in the product datasheet of the semiconductor device used in the semiconductor module.

For example, features of the present disclosure are as follows: a method for manufacturing a semiconductor module in which a semiconductor device is face-down mounted above a mounting substrate using a stencil, wherein the semiconductor device includes: n (n is an integer of 2 or more) pads disposed in an upper surface of the semiconductor device, the mounting substrate includes n lands corresponding one-to-one to the n pads, the stencil includes n apertures corresponding one-to-one to the n pads, when Pa denotes the area in the plan view of the semiconductor device of the closest pad that is closest to the center of the semiconductor device among the n pads in the plan view of the semiconductor device, Pb denotes the area in the plan view of the semiconductor device of the farthest pad thereamong, La denotes the area in the plan view of the mounting substrate of the closest land corresponding to the closest pad among the n lands, Lb denotes the area in the plan view of the mounting substrate of the farthest land corresponding to the farthest pad thereamong, Sa denotes the area in the plan view of the stencil of the closest aperture corresponding to the closest pad among the n apertures, and Sb denotes the area in the plan view of the stencil of the farthest aperture corresponding to the farthest pad thereamong, Sa is smaller than each of Pa and La and/or Sb is larger than each of Pb and Lb. The features can be said to be equivalent to being able to confirm the relationship in the above features among (i) the pad pattern and the recommended land pattern and (ii) the recommended stencil pattern, which are included in the product datasheet of the semiconductor device used in the semiconductor module.

### <Consideration>

Below, in semiconductor module 1 described above, an intended relationship between the shapes of n pads 101 and the shapes of n lands 201 in cases where for each of n pads 101, the shape of that pad 101 in the plan view of semiconductor device 100 and the shape of land 201 corresponding to that pad 101 in the plan view of mounting substrate 200 are not necessarily the same will be considered.

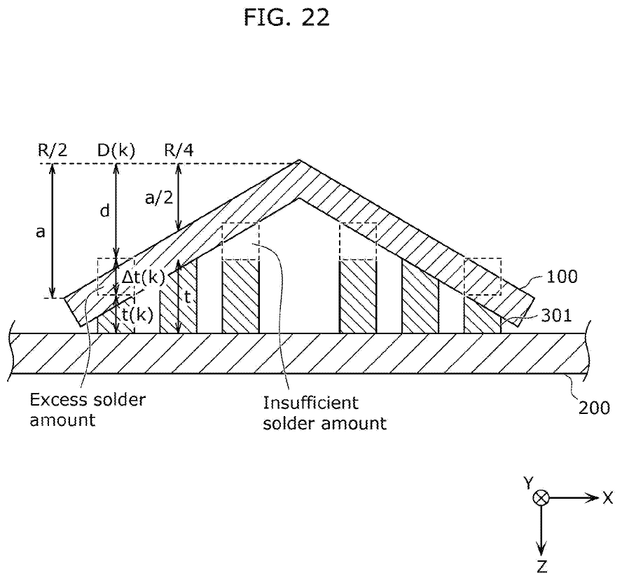

FIG. 22 is a schematic cross-sectional view for explaining an intended relationship between the shapes of n pads 101 and the shapes of n lands 201.

As shown in FIG. 22, description is given here, assuming that the warpage of semiconductor device 100 is approximated as if it were a linear change, the distance from the center of semiconductor device 100 to the center of each of the n pads indexed by k in the plan view of semiconductor device 100 is denoted by D(k), ¼ of the length of the diagonal of semiconductor device 100 in the plan view of semiconductor device 100 is denoted as reference radius r, the height of solder bonding material 301 at the position where the distance from the center of semiconductor device 100 is the reference radius r in the plan view of semiconductor device 100 is denoted by t, and the curvature magnitude of semiconductor device 100 is denoted by a.

As shown in FIG. 22, when semiconductor device 100 warps so as to curve projectingly in a direction in which the center of semiconductor device 100 is away from mounting substrate 200, in general, the amount of solder bonding material 301 at a position where the distance from the center of semiconductor device 100 is r in the plan view of semiconductor device 100 is neither excessive nor insufficient in the plan view of semiconductor device 100, the amount of solder bonding material 301 at a position where the distance from the center of semiconductor device 100 is shorter than r in the plan view of semiconductor device 100 is insufficient, and the amount of solder bonding material 301 at a position where the distance from the center of semiconductor device 100 is longer than r in the plan view of semiconductor device 100 is excessive.

Here, when considering solder bonding material 301 in pad 101 where D(k) is longer than r, solder bonding material 301 is pressed toward land 201 due to the warpage of semiconductor device 100.

Thus, if Δt(k) denotes the amount (height) by which solder bonding material 301 is pressed in, Δt(k) is expressed by Equation A as follows.

$$Δ t ( k ) = ( 2 \times D ( k ) / R - 1 / 2 ) \times a \qquad ( Equation A )$$

Here, diagonal length R is, as previously described, the length of the diagonal of semiconductor device 100 in the plan view of semiconductor device 100.

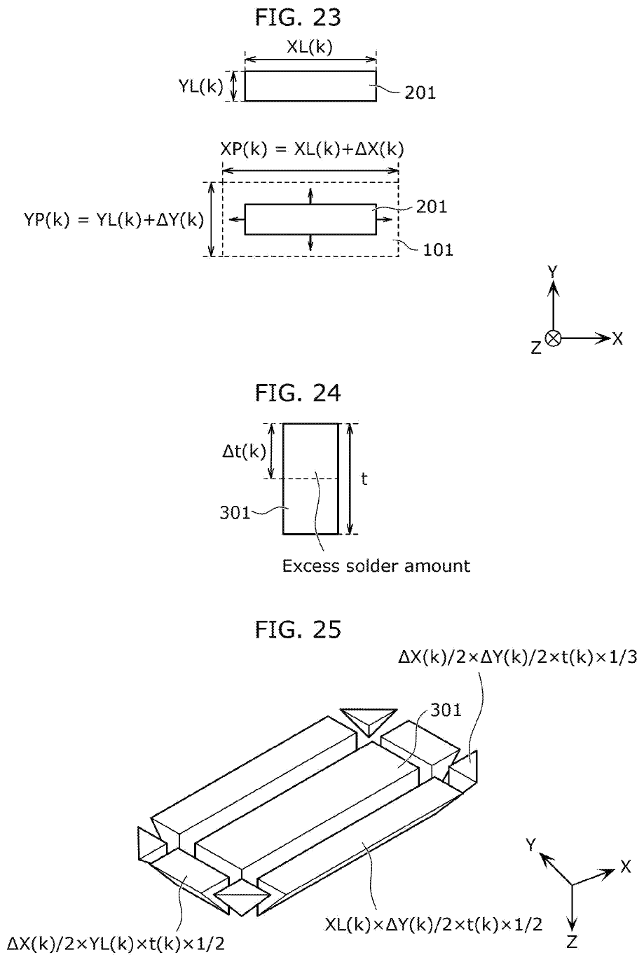

FIG. 23 is a plan schematic diagram for explaining an intended relationship between the shapes of n pads 101 and the shapes of n lands 201.

As shown in FIG. 23, a description is given here, assuming that XL(k) denotes the length in the first direction (the X-axis direction in FIG. 23) of each of n lands 201 indexed by k in the plan view of mounting substrate 200, YL(k) denotes the length in the second direction (the Y-axis direction in FIG. 23) of each of n lands 201 indexed by k in the plan view of mounting substrate 200, XP(k) denotes the length in the first direction of each of n pads 101 indexed by k in the plan view of semiconductor device 100, and YP(k) denotes the length in the second direction of each of n pads 101 indexed by k in the plan view of semiconductor device 100.

Also, a description is given here, assuming that in the plan view of mounting substrate 200, the shape of each of lands 201 indexed by k and the shape of solder bonding material 301 provided above that k-th land 201 are the same.

Note that here, as shown in FIG. 23, discussion is conducted using, as an example, the case where the area of k-th pad 101 in the plan view of semiconductor device 100 is larger than the area of k-th land 201 in the plan view of mounting substrate 200; however, also in the case where the area of k-th pad 101 in the plan view of semiconductor device 100 is smaller than the area of k-th land 201 in the plan view of mounting substrate 200, the same discussion holds by replacing XP(k) with XL(k) and replacing YP(k) with YL(k).

FIG. 24 is a schematic cross-sectional view for explaining an intended relationship between the shapes of n pads 101 and the shapes of n lands 201.

FIG. 25 is a schematic perspective view for explaining an intended relationship between the shapes of n pads 101 and the shapes of n lands 201.

As can be seen from FIGS. 23 and 24, the excess volume of solder bonding material 301 corresponding to k-th land 201 is Δt(k)×XL(k)×YL(k).

Accordingly, the area of k-th pad 101 in the plan view of semiconductor device 100 may be made larger than the area of k-th land 201 in the plan view of mounting substrate 200, thereby allowing this excess volume to escape.

In this case, if the shape of k-th pad 101 in the plan view of semiconductor device 100 is expanded by ΔX(k) in the first direction and by ΔY(k) in the second direction relative to the shape of k-th land 201 in the plan view of mounting substrate 200, thereby allowing this excess volume to escape, then as shown in FIG. 25, excess volume V(k) is expressed by Equation B as below.

$$V ( k ) = t ( k ) \times Δ X ( k ) \times YL ( k ) / 2 + t ( k ) \times XL ( k ) \times Δ Y ( k ) / 2 + t ( k ) \times Δ X ( k ) \times Δ Y ( k ) / 3 = t ( k ) \times ( Δ X ( k ) \times YL ( k ) / 2 + XL ( k ) \times Δ Y ( k ) / 2 + Δ X ( k ) \times Δ Y ( k ) / 3 ) \\ Here , t ( k ) = t - Δ t ( k ) . \qquad ( Equation B )$$

Thus, from the fact that t(k)=t−Δt(k) and from Equations A and B, in the case where semiconductor device 100 warps so as to curve projectingly in the direction in which the center of semiconductor device 100 is away from mounting substrate 200, when the area of k-th pad 101 in the plan view of semiconductor device 100 is larger than the area of k-th land 201 in the plan view of mounting substrate 200, for pad 101 where D(k) is shorter than r, it can be said that the following relationship may be satisfied.

$$Δ X ( k ) \times YL ( k ) / 2 + XL ( k ) \times Δ Y ( k ) / 2 - Δ X ( k ) \times Δ Y ( k ) / 3 = XL ( k ) \times YL ( k ) / [ - t \{ ( 2 \times D ( k ) / R - 1 / 2 ) \times a \} + 1 ]$$

Similarly, in the case where semiconductor device 100 warps so as to curve projectingly in the direction in which the center of semiconductor device 100 is away from mounting substrate 200, when the area of k-th pad 101 in the plan view of semiconductor device 100 is larger than the area of k-th land 201 in the plan view of mounting substrate 200, for pad 101 where D(k) is longer than r, it can be said that the following relationship may be satisfied.

$$Δ X ( k ) \times YL ( k ) / 2 + XL ( k ) \times Δ Y ( k ) / 2 + Δ X ( k ) \times Δ Y ( k ) / 3 = XL ( k ) \times YL ( k ) / [ t \{ ( 2 \times D ( k ) / R - 1 / 2 ) \times a \} - 1 ]$$

Similarly, in the case where semiconductor device 100 warps so as to curve projectingly in the direction in which the center of semiconductor device 100 is away from mounting substrate 200, when the area of k-th pad 101 in the plan view of semiconductor device 100 is smaller than the area of k-th land 201 in the plan view of mounting substrate 200, for pad 101 where D(k) is shorter than r, it can be said that the following relationship may be satisfied.

$$Δ X ( k ) \times YP ( k ) / 2 + XP ( k ) \times Δ Y ( k ) / 2 - Δ X ( k ) \times Δ Y ( k ) / 3 = XP ( k ) \times YP ( k ) / [ - t \{ ( 2 \times D ( k ) / R - 1 / 2 ) \times a \} + 1 ]$$

Similarly, in the case where semiconductor device 100 warps so as to curve projectingly in the direction in which the center of semiconductor device 100 is away from mounting substrate 200, when the area of k-th pad 101 in the plan view of semiconductor device 100 is smaller than the area of k-th land 201 in the plan view of mounting substrate 200, for pad 101 where D(k) is longer than r, it can be said that the following relationship may be satisfied.

$$Δ X ( k ) \times YL ( k ) / 2 + XL ( k ) \times Δ Y ( k ) / 2 + Δ X ( k ) \times Δ Y ( k ) / 3 = XL ( k ) \times YL ( k ) / [ t \{ ( 2 \times D ( k ) / R - 1 / 2 ) \times a \} - 1 ] \\ Here , Δ X ( k ) = \vert XP ( k ) - XL ( k ) \vert and Δ Y ( k ) = \vert YP ( k ) - YL ( k ) \vert .$$

Thus, for each of one or more inner pads located inside the circle centered at the center of semiconductor device 100 in the plan view of semiconductor device 100 among n pads 101 indexed by k,

$$\vert XP ( k ) - XL ( k ) \vert \times YL ( k ) / 2 + XL ( k ) \times \vert YP ( k ) - YL ( k ) \vert / 2 - \vert XP ( k ) - XL ( k ) \vert \times \vert YP ( k ) - YL ( k ) \vert / 3 = XL ( k ) \times YL ( k ) / [ - t / \{ ( 2 \times D ( k ) / R - 1 / 2 ) \times a \} + 1 ] \\ or \\ \vert XP ( k ) - XL ( k ) \vert \times YP ( k ) / 2 + XP ( k ) \times \vert YP ( k ) - YL ( k ) \vert / 2 - \vert XP ( k ) - XL ( k ) \vert \times \vert YP ( k ) - YL ( k ) \vert / 3 = XP ( k ) \times YP ( k ) / [ - t / \{ ( 2 \times D ( k ) / R - 1 / 2 ) \times a \} + 1 ]$$

may be satisfied, and for each of one or more outer pads located outside the above circle in the plan view of semiconductor device 100 among n pads 101 indexed by k,

$$\vert XP ( k ) - XL ( k ) \vert \times YL ( k ) / 2 + XL ( k ) \times \vert YP ( k ) - YL ( k ) \vert / 2 + \vert XP ( k ) - XL ( k ) \vert \times \vert YP ( k ) - YL ( k ) \vert / 3 = XL ( k ) \times YL ( k ) / [ t / \{ ( 2 \times D ( k ) / R - 1 / 2 ) \times a \} - 1 ] \\ or \\ \vert XP ( k ) - XL ( k ) \vert \times YP ( k ) / 2 + XP ( k ) \times \vert YP ( k ) - YL ( k ) \vert / 2 + \vert XP ( k ) - XL ( k ) \vert \times \vert YP ( k ) - YL ( k ) \vert / 3 = XP ( k ) \times YP ( k ) / [ t / \{ ( 2 \times D ( k ) / R - 1 / 2 ) \times a \} - 1 ]$$

may be satisfied.

Next, in semiconductor module 1 described above, an intended relationship between the shapes of n pads 101 and the shapes of n apertures 401 in cases where for each of n pads 101, the shape of that pad 101 in the plan view of semiconductor device 100 and the shape of land 201 corresponding to that pad 101 in the plan view of mounting substrate 200 are the same will be considered.

As shown in FIG. 22, also here, description is given assuming that the warpage of semiconductor device 100 is approximated as if it were a linear change, the distance from the center of semiconductor device 100 to the center of each of the n pads indexed by k in the plan view of semiconductor device 100 is denoted by D(k), ¼ of the length of the diagonal of semiconductor device 100 in the plan view of semiconductor device 100 is denoted as reference radius r, the height of solder bonding material 301 at a position where the distance from the center of semiconductor device 100 is the reference radius r in the plan view of semiconductor device 100 is denoted by t, and the curvature magnitude of semiconductor device 100 is denoted by a.

As described above, when semiconductor device 100 warps so as to curve projectingly in a direction in which the center of semiconductor device 100 is away from mounting substrate 200 as shown in FIG. 22, in general, the amount of solder bonding material 301 at a position where the distance from the center of semiconductor device 100 is r in the plan view of semiconductor device 100 is neither excessive nor insufficient, the amount of solder bonding material 301 at a position where the distance from the center of semiconductor device 100 in the plan view of semiconductor device 100 is shorter than r is insufficient, and the amount of solder bonding material 301 at a position where the distance from the center of semiconductor device 100 is longer than r in the plan view of semiconductor device 100 is excessive.

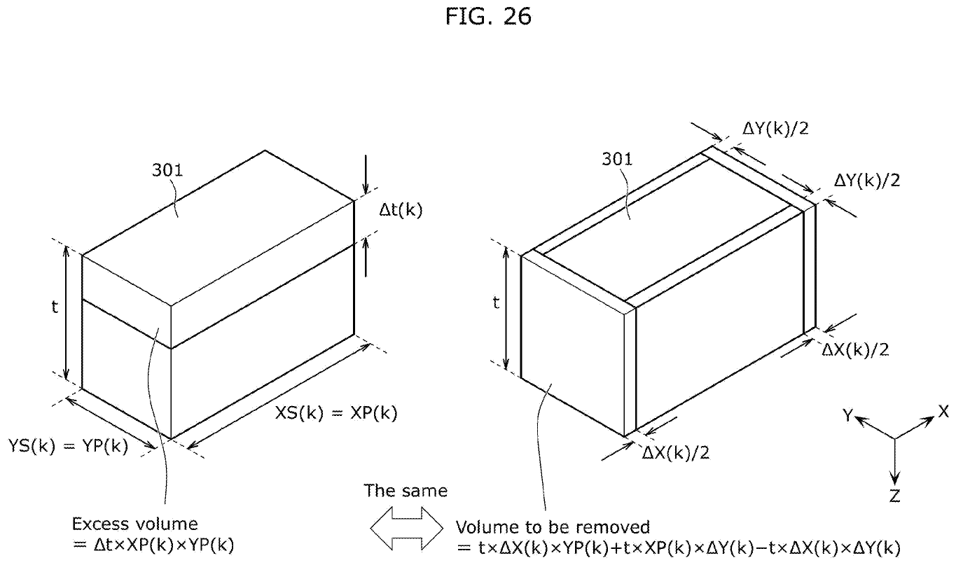

FIG. 26 is a schematic perspective view for explaining an intended relationship between the shapes of n pads 101 and the shapes of n apertures 401.

As shown in FIG. 26, a description is given here, assuming that XS(k) denotes the length in the first direction (the X-axis direction in FIG. 25) of each of n apertures 401 indexed by k in the plan view of stencil 400, and YS(k) denotes the length in the second direction (the Y-axis direction in FIG. 25) of each of n apertures 401 indexed by k in the plan view of stencil 400.

Furthermore, a description is given, assuming that as shown in FIG. 23, XP(k) denotes the length in the first direction (the X-axis direction in FIG. 2) of each of n pads 101 indexed by k in the plan view of semiconductor device 100, and YP(k) denotes the length in the second direction (the Y-axis direction in FIG. 23) of each of n pads 101 indexed by k in the plan view of semiconductor device 100.

As can be seen from FIG. 26, when considering solder bonding material 301 for pad 101 where D(k) is longer than r, when the area of aperture 401 corresponding to k-th pad 101 in the plan view of stencil 400 is the same as the area of k-th pad 101 in the plan view of semiconductor device 100, the excess volume of solder bonding material 301 corresponding to k-th pad 101 is Δt(k)×XL(k)×YL(k).

Thus, this excess volume may be reduced by making the area of aperture 401 corresponding to k-th pad 101 in the plan view of stencil 400 smaller than the area of k-th pad 101 in the plan view of semiconductor device 100.

In this case, if the shape of aperture 401 corresponding to k-th pad 101 in the plan view of stencil 400 is narrowed by ΔX(k) in the first direction and by ΔY(k) in the second direction relative to the shape of k-th land 201 in the plan view of semiconductor device 100 to thus reduce this excess volume, then excess volume V(k) is expressed by Equation C as follows, as shown in FIG. 26.

$$V ( k ) = t \times Δ X ( k ) \times YP ( k ) + t \times XP ( k ) \times Δ Y ( k ) - t \times Δ X ( k ) \times Δ Y ( k ) \qquad ( Equation C )$$

Thus, from Equations A and C, in the case where semiconductor device 100 warps so as to curve projectingly in the direction in which the center of semiconductor device 100 is away from mounting substrate 200, when the area of k-th pad 101 in the plan view of semiconductor device 100 is the same as the area of k-th land 201 in the plan view of mounting substrate 200, for pad 101 where D(k) is longer than r, it can be said that the following relationship may be satisfied.

$$Δ X ( k ) \times YP ( k ) + XP ( k ) \times Δ Y ( k ) - Δ X ( k ) \times Δ Y ( k ) = \{ ( 2 \times D ( k ) / R - 1 / 2 ) \times a \} / t \times XP ( k ) \times YP ( k )$$

Similarly, in the case where semiconductor device 100 warps so as to curve projectingly in the direction in which the center of semiconductor device 100 is away from mounting substrate 200, when the area of k-th pad 101 in the plan view of semiconductor device 100 is the same as the area of k-th land 201 in the plan view of mounting substrate 200, for pad 101 where D(k) is shorter than r, it can be said that the following relationship may be satisfied.

$$Δ X ( k ) \times YP ( k ) + XP ( k ) \times Δ Y ( k ) + Δ X ( k ) \times Δ Y ( k ) = - \{ ( 2 \times D ( k ) / R - 1 / 2 ) \times a \} / t \times XP ( k ) \times YP ( k ) \\ Here , Δ X ( k ) = \vert XP ( k ) - XS ( k ) \vert and Δ Y ( k ) = \vert YL ( k ) - YS ( k ) \vert .$$

Thus, for each of one or more inner pads located inside the circle centered at the center of semiconductor device 100 in the plan view of semiconductor device 100 among n pads 101 indexed by k,

$$\vert XP ( k ) - XS ( k ) \vert \times YP ( k ) + XP ( k ) \times \vert YP ( k ) - YS ( k ) \vert + \vert XP ( k ) - XS ( k ) \vert \times \vert YP ( k ) - YS ( k ) \vert = - \{ ( 2 \times D ( k ) / R - 1 / 2 ) \times a \} / t \times XP ( k ) \times YP ( k )$$

may be satisfied, and for each of one or more outer pads located outside the above circle in the plan view of semiconductor device 100 among n pads 101 indexed by k,

$$\vert XP ( k ) - XS ( k ) \vert \times YP ( k ) + XP ( k ) \times \vert YP ( k ) - YS ( k ) \vert - \vert XP ( k ) - XS ( k ) \vert \times \vert YP ( k ) - YS ( k ) \vert = \{ ( 2 \times D ( k ) / R - 1 / 2 ) \times a \} / t \times XP ( k ) \times YP ( k )$$

may be satisfied.

### (Supplementary Note)

The semiconductor devices according to aspects of the present disclosure have been described above based on the embodiments, yet the present disclosure is not limited to the above embodiments. The scope of one or more aspects of the present disclosure may also encompass embodiments resulting from applying, to the embodiments, various modifications that may be conceived by those skilled in the art without departing from the spirit of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to a semiconductor module in which a semiconductor device is mounted above a mounting substrate.

1. A semiconductor module in which a semiconductor device of a chip-size package type is face-down mounted above a mounting substrate, the semiconductor device including one or more vertical metal oxide semiconductor (MOS) transistors,
wherein the semiconductor device includes:
a semiconductor layer;
a metal layer stacked on the semiconductor layer and in contact with a lower surface of the semiconductor layer; and
n pads disposed in an upper surface of the semiconductor device, n being an integer of 2 or more,
the semiconductor device is curved projectingly in a direction in which a center of the semiconductor device in a plan view of the semiconductor device is away from the mounting substrate,
the mounting substrate includes n lands corresponding one-to-one to the n pads,
each of the n pads is joined by solder bonding material to one of the n lands corresponding to the pad, and
when with use of n mutually distinct values of k, where k is an integer between 1 and n, inclusive, each of the n pads is denoted as a k-th pad, each of the n lands corresponding to the n pads indexed by k is denoted as a k-th land, an area of each of the n pads indexed by k in the plan view of the semiconductor device is denoted by P(k), an area of each of the n lands indexed by k in a plan view of the mounting substrate is denoted by L(k), and a distance in the plan view of the semiconductor device from the center of the semiconductor device to a center of each of the n pads indexed by k is denoted by D(k),
the n pads indexed by k and the n lands indexed by k include a k1-th pad and a k1-th land satisfying P(k1)=L(k1), the k1-th pad and the k1-th land being identical in shape in the plan view of the semiconductor device,
the n pads indexed by k and the n lands indexed by k include a k2-th pad and a k2-th land satisfying D(k1)<D(k2) and P(k2)/L(k2)<1, and
in the plan view of the semiconductor device, the k2-th land includes a region that does not overlap the k2-th pad, in a region farther from the center of the semiconductor device than a center of the k2-th land.

2. The semiconductor module according to claim 1,
wherein in the plan view of the semiconductor device, a nearest distance between a perimeter of the k2-th land and the center of the semiconductor device is no shorter than a nearest distance between a perimeter of the k2-th pad and the center of the semiconductor device.

3. The semiconductor module according to claim 1,
wherein in the plan view of the semiconductor device, the k1-th pad overlaps a portion of a circumference of a circle centered at the center of the semiconductor device in the plan view of the semiconductor device, the circle having a radius denoted by r determined by
$$r = \frac{{\sum }_{k = 1}^{n} D ( k ) \times P ( k )}{{\sum }_{k = 1}^{n} P ( k )} , \qquad [ Math 1 ]$$
and
a center of the k2-th pad is located outside the circle.

4. The semiconductor module according to claim 3,
wherein the k1-th pad and the k2-th pad are each a source pad of a vertical MOS transistor among the one or more vertical MOS transistors.

5. A semiconductor module in which a semiconductor device of a chip-size package type is face-down mounted above a mounting substrate, the semiconductor device including one or more vertical metal oxide semiconductor (MOS) transistors,
wherein the semiconductor device includes:
a semiconductor layer;
a metal layer stacked on the semiconductor layer and in contact with a lower surface of the semiconductor layer; and
n pads disposed in an upper surface of the semiconductor device, n being an integer of 2 or more,
the semiconductor device is curved projectingly in a direction in which a center of the semiconductor device in a plan view of the semiconductor device is away from the mounting substrate,
the mounting substrate includes n lands corresponding one-to-one to the n pads,
each of the n pads is joined by solder bonding material to one of the n lands corresponding to the pad, and
when with use of n mutually distinct values of k, where k is an integer between 1 and n, inclusive, each of the n pads is denoted as a k-th pad, each of the n lands corresponding to the n pads indexed by k is denoted as a k-th land, an area of each of the n pads indexed by k in the plan view of the semiconductor device is denoted by P(k), an area of each of the n lands indexed by k in a plan view of the mounting substrate is denoted by L(k), and a distance in the plan view of the semiconductor device from the center of the semiconductor device to a center of each of the n pads indexed by k is denoted by D(k),
the n pads indexed by k and the n lands indexed by k include a k1-th pad and a k1-th land satisfying P(k1)=L(k1), the k1-th pad and the k1-th land being identical in shape in the plan view of the semiconductor device, and
the n pads indexed by k and the n lands indexed by k include a k3-th pad and a k3-th land satisfying D(k1)>D(k3) and P(k3)/L(k3)>1.

6. The semiconductor module according to claim 5,
wherein in the plan view of the semiconductor device, a center of the k3-th pad coincides with a center of the k3-th land.

7. The semiconductor module according to claim 5,
wherein in the plan view of the semiconductor device, the k1-th pad overlaps a portion of a circumference of a circle centered at the center of the semiconductor device in the plan view of the semiconductor device, the circle having a radius denoted by r determined by
$$r = \frac{{\sum }_{k = 1}^{n} D ( k ) \times P ( k )}{{\sum }_{k = 1}^{n} P ( k )} , \qquad [ Math 2 ]$$
and
a center of the k3-th pad is located inside the circle.

8. The semiconductor module according to claim 7,
wherein the k1-th pad and the k3-th pad are each a source pad of a vertical MOS transistor among the one or more vertical MOS transistors.

9. The semiconductor module according to claim 1,
wherein P(k)/L(k) monotonically decreases as D(k) increases.

10. The semiconductor module according to claim 5,
wherein P(k)/L(k) monotonically decreases as D(k) increases.

11. A method for manufacturing a semiconductor module by face-down mounting a semiconductor device of a chip-size package type above a mounting substrate using a stencil, the semiconductor device including one or more vertical metal oxide semiconductor (MOS) transistors,
wherein the semiconductor device includes:
a semiconductor layer;
a metal layer stacked on the semiconductor layer and in contact with a lower surface of the semiconductor layer; and
n pads disposed in an upper surface of the semiconductor device, n being an integer of 2 or more,
the semiconductor device is curved projectingly in a direction in which a center of the semiconductor device in a plan view of the semiconductor device is away from the mounting substrate,
the mounting substrate includes n lands corresponding one-to-one to the n pads,
the stencil includes n apertures corresponding one-to-one to the n pads,
each of the n apertures is an aperture for providing, above one of the n lands corresponding to the aperture, solder bonding material for joining one of the n pads corresponding to the aperture and the one of the n lands,
when Pa denotes an area of a closest pad among the n pads in the plan view of the semiconductor device, La denotes an area of a closest land among the n lands in a plan view of the mounting substrate, and Sa denotes an area of a closest aperture among the n apertures in a plan view of the stencil, the closest pad being closest to the center of the semiconductor device in the plan view of the semiconductor device, the closest land corresponding to the closest pad, the closest aperture corresponding to the closest pad,
Sa is larger than each of Pa and La, and
the method comprises:
a first process of providing the solder bonding material above each of the n lands by using the stencil; and
a second process of joining each of the n pads to one land corresponding to the pad among the n lands by performing reflow processing, using the solder bonding material provided above the one land by performing the first process.

12. The method according to claim 11,
wherein when with use of n mutually distinct values of k, where k is an integer between 1 and n, inclusive, each of the n pads is denoted as a k-th pad, each of the n apertures corresponding to the n pads indexed by k is denoted as a k-th aperture, an area of each of the n pads indexed by k in the plan view of the semiconductor device is denoted by P(k), an area of each of the n apertures indexed by k in the plan view of the stencil is denoted by S(k), and a distance in the plan view of the semiconductor device from the center of the semiconductor device to a center of each of the n pads indexed by k is denoted by D(k),
for each of one or more inner pads among the n pads indexed by k,
S(k)/P(k) is greater than 1, the one or more inner pads each having a center located inside a circle in the plan view of the semiconductor device, the circle being centered at the center of the semiconductor device in the plan view of the semiconductor device and having a radius denoted by r determined by
$$r = \frac{{\sum }_{k = 1}^{n} D ( k ) \times P ( k )}{{\sum }_{k = 1}^{n} P ( k )} . \qquad [ Math 3 ]$$

13. The method according to claim 11,
wherein when with use of n mutually distinct values of k, where k is an integer between 1 and n, inclusive, each of the n pads is denoted as a k-th pad, each of the n lands corresponding to the n pads indexed by k is denoted as a k-th land, each of the n apertures corresponding to the n pads indexed by k is denoted as a k-th aperture, an area of each of the n pads indexed by k in the plan view of the semiconductor device is denoted by P(k), an area of each of the n lands indexed by k in the plan view of the mounting substrate is denoted by L(k), an area of each of the n apertures indexed by k in the plan view of the stencil is denoted by S(k), and a distance in the plan view of the semiconductor device from the center of the semiconductor device to a center of each of the n pads indexed by k is denoted by D(k),
for each of one or more inner pads among the n pads indexed by k,
S(k)/L(k) is greater than 1, the one or more inner pads each having a center located inside a circle in the plan view of the semiconductor device, the circle being centered at the center of the semiconductor device in the plan view of the semiconductor device and having a radius denoted by r determined by
$$r = \frac{{\sum }_{k = 1}^{n} D ( k ) \times P ( k )}{{\sum }_{k = 1}^{n} P ( k )} . \qquad [ Math 4 ]$$

14. A method for manufacturing the semiconductor module according to claim 1 using a stencil,
wherein the stencil includes n apertures corresponding one-to-one to the n pads,
each of the n apertures is an aperture for providing, above one of the n lands corresponding to the aperture, solder bonding material for joining one of the n pads corresponding to the aperture and the one of the n lands,
when Pa denotes an area of a closest pad among the n pads in the plan view of the semiconductor device, La denotes an area of a closest land among the n lands in the plan view of the mounting substrate, and Sa denotes an area of a closest aperture among the n apertures in a plan view of the stencil, the closest pad being closest to the center of the semiconductor device in the plan view of the semiconductor device, the closest land corresponding to the closest pad, the closest aperture corresponding to the closest pad,
Sa is larger than each of Pa and La, and
the method comprises:
a first process of providing the solder bonding material above each of the n lands by using the stencil; and
a second process of joining each of the n pads to one land corresponding to the pad among the n lands by performing reflow processing, using the solder bonding material provided above the one land by performing the first process.

15. A method for manufacturing the semiconductor module according to claim 5 using a stencil,
wherein the stencil includes n apertures corresponding one-to-one to the n pads,
each of the n apertures is an aperture for providing, above one of the n lands corresponding to the aperture, solder bonding material for joining one of the n pads corresponding to the aperture and the one of the n lands,
when Pa denotes an area of a closest pad among the n pads in the plan view of the semiconductor device, La denotes an area of a closest land among the n lands in the plan view of the mounting substrate, and Sa denotes an area of a closest aperture among the n apertures in a plan view of the stencil, the closest pad being closest to the center of the semiconductor device in the plan view of the semiconductor device, the closest land corresponding to the closest pad, the closest aperture corresponding to the closest pad,
Sa is larger than each of Pa and La, and
the method comprises:
a first process of providing the solder bonding material above each of the n lands by using the stencil; and
a second process of joining each of the n pads to one land corresponding to the pad among the n lands by performing reflow processing, using the solder bonding material provided above the one land by performing the first process.

16. A method for manufacturing the semiconductor module according to claim 1 using a stencil,
wherein the stencil includes n apertures corresponding one-to-one to the n pads,
each of the n apertures is an aperture for providing, above one of the n lands corresponding to the aperture, solder bonding material for joining one of the n pads corresponding to the aperture and the one of the n lands,
when Pb denotes an area of a farthest pad among the n pads in the plan view of the semiconductor device, Lb denotes an area of a farthest land among the n lands in the plan view of the mounting substrate, and Sb denotes an area of a farthest aperture among the n apertures in a plan view of the stencil, the farthest pad being farthest from the center of the semiconductor device in the plan view of the semiconductor device, the farthest land corresponding to the farthest pad, the farthest aperture corresponding to the farthest pad,
Sb is smaller than each of Pb and Lb, and
the method comprises:
a first process of providing the solder bonding material above each of the n lands by using the stencil; and
a second process of joining each of the n pads to one land corresponding to the pad among the n lands by performing reflow processing, using the solder bonding material provided above the one land by performing the first process.

17. A method for manufacturing the semiconductor module according to claim 5 using a stencil,
wherein the stencil includes n apertures corresponding one-to-one to the n pads,
each of the n apertures is an aperture for providing, above one of the n lands corresponding to the aperture, solder bonding material for joining one of the n pads corresponding to the aperture and the one of the n lands,
when Pb denotes an area of a farthest pad among the n pads in the plan view of the semiconductor device, Lb denotes an area of a farthest land among the n lands in the plan view of the mounting substrate, and Sb denotes an area of a farthest aperture among the n apertures in a plan view of the stencil, the farthest pad being farthest from the center of the semiconductor device in the plan view of the semiconductor device, the farthest land corresponding to the farthest pad, the farthest aperture corresponding to the farthest pad,
Sb is smaller than each of Pb and Lb, and
the method comprises:
a first process of providing the solder bonding material above each of the n lands by using the stencil; and
a second process of joining each of the n pads to one land corresponding to the pad among the n lands by performing reflow processing, using the solder bonding material provided above the one land by performing the first process.
